(19) United States
(12) Patent Application Publication
(10) Pub. No.: US 2026/0068439 A1
(43) Pub. Date: Mar. 5, 2026

(54) DISPLAY PANEL AND DISPLAY DEVICE INCLUDING THE SAME

(71) Applicant: LG Display Co., Ltd., Seoul (KR)

(72) Inventor: Seungmin BAIK, Gimpo-si (KR)

(73) Assignee: LG Display Co., Ltd., Seoul (KR)

(21) Appl. No.: 19/263,068

(22) Filed: Jul. 8, 2025

(30) Foreign Application Priority Data
Sep. 2, 2024 (KR) 10-2024-0118567

(51) Int. Cl. H10K 59/122; H10K 50/13; H10K 50/19

(52) U.S. Cl. CPC H10K 59/122; H10K 50/13; H10K 50/19

(57) ABSTRACT

A display panel and a display device prevent a short-circuit between charge generation layers of adjacent sub-pixels using a first trench defined between adjacent ones of a plurality of sub-pixels, and prevent a short-circuit between charge generation layers arranged in a vertical direction using a structure disposed on the first trench.

### CROSS-REFERENCE TO RELATED APPLICATION

This application claims priority from Korean Patent Application No. 10-2024-0118567 filed on Sep. 2, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display panel and a display device including the display panel.

### Description of Related Art

Display devices are implemented in a wide variety of forms, such as televisions, monitors, smartphones, tablet PC, laptops, wearable devices, etc.

An organic light-emitting display (OLED) among the display devices displaying various information based on an image is a self-luminous device that emits light by itself, and has advantages in that a response speed is fast, light emission efficiency and luminance are high and a viewing angle is wide, and a contrast ratio and a color gamut are excellent.

Recently, as users' demands for high-quality images increase, development of a high-resolution display device is actively progressing.

### BRIEF SUMMARY

As a resolution of the display device becomes higher, the number of sub-pixels included in the display device increases, and thus a spacing between the sub-pixels becomes smaller.

As the spacing between the sub-pixels SP becomes smaller, a lateral leakage current (LLC) may be generated between the sub-pixels SP adjacent to each other.

When, described above, the lateral leakage current is generated between the sub-pixels adjacent to each other, unwanted sub-pixels also emit light, and thus the color gamut of the display device may be deteriorated.

The organic light-emitting display device may have a tandem structure having a plurality of stacks in which organic light-emitting layers are stacked on top of each other in order to increase light emission intensity.

A charge generation layer (CGL) may be positioned between adjacent stacks among the plurality of stacks and may generate electrons and transfer the electrons to the organic light-emitting layer included in both stacks around the CGL.

For example, one charge generation layer may be disposed in a structure in which two stacks are vertically arranged vertically. Alternatively, two charge generation layers may be disposed in a structure in which three stacks are vertically arranged vertically.

For example, in a structure in which the two stacks are vertically arranged, when charge generation layers between adjacent sub-pixels are connected to each other, the lateral leakage current may occur.

In another example, in a structure in which the three or more stacks are vertically arranged, when a plurality of charge generation layers stacked in the vertical direction are connected to each other, a short-circuit between the charge generation layers stacked in the vertical direction may occur, such that a forward leakage current (FLC) may also occur. Therefore, in a structure in which the three or more stacks are vertically arranged, not only the lateral leakage current (LLC) but also the forward leakage current (FLC) may occur.

When the forward leakage current is generated as described above, a small amount of current may flow even in a state in which the organic light-emitting display device is turned off.

Accordingly, through various experiments, the inventors of the present disclosure have invented a display panel and a display device including the same which may be capable of reducing the generation of the lateral leakage current and the forward leakage current that may occur due to the short-circuit between the charge generation layers.

A purpose of embodiments of the present disclosure provides a display panel which may prevent a short-circuit between charge generation layers of adjacent sub-pixels, and a display device including the same.

Another purpose of the present disclosure is to provide a display panel capable of preventing a short-circuit between adjacent ones of a plurality of charge generation layers arranged in a vertical direction and a display device including the same.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A display panel according to an embodiment of the present disclosure includes: a substrate having a plurality of sub-pixel areas corresponding to a plurality of sub-pixels; an insulating layer disposed on the substrate; a first trench defined in the insulating layer, wherein the first trench is disposed between adjacent ones of the plurality of sub-pixel areas; and a structure disposed on the first trench and spaced apart from the first trench, wherein the structure extends along an extension direction of the first trench.

A display panel according to another embodiment of the present disclosure includes: a substrate having a plurality of sub-pixel areas corresponding to a plurality of sub-pixels; an insulating layer disposed on the substrate; a first trench defined in the insulating layer, wherein the first trench is disposed between adjacent ones of the plurality of sub-pixel areas; and a second trench disposed on top of the first trench and spaced apart from the first trench, wherein the second trench overlaps the first trench in a vertical direction.

A display panel according to still another embodiment of the present disclosure includes: a substrate having a plurality of sub-pixel areas corresponding to a plurality of sub-pixels; an insulating layer disposed on the substrate; a first trench defined in the insulating layer, wherein the first trench is disposed between adjacent ones of the plurality of sub-pixel areas; and a structure disposed on the first trench and spaced apart from the first trench, wherein the structure includes a stem overlapping the first trench in a vertical direction.

A display device according to still yet another embodiment of the present disclosure includes: a casing; and at least one display panel accommodated in the casing, wherein each of the at least one display panel includes the display panel as described above.

According to an embodiment of the present disclosure, a short-circuit between charge generation layers of adjacent sub-pixels may be prevented via the first trench defined between adjacent ones of the plurality of sub-pixels, and a short-circuit between charge generation layers arranged in the vertical direction as well as a short-circuit between charge generation layers of adjacent sub-pixels may be prevented via the structure disposed on the first trench.

In addition, according to an embodiment of the present disclosure, a short-circuit between charge generation layers of adjacent sub-pixels may be prevented via the first trench defined between adjacent ones of the plurality of sub-pixels, and a short-circuit between charge generation layers arranged in the vertical direction as well as a short-circuit between charge generation layers of adjacent sub-pixels may be prevented via the second trench disposed to overlap the first trench in the vertical direction.

In addition, according to an embodiment of the present disclosure, a short-circuit between charge generation layers of adjacent sub-pixels may be prevented via the first trench defined between adjacent ones of the plurality of sub-pixels, and a short-circuit between charge generation layers arranged in the vertical direction as well as a short-circuit between charge generation layers of adjacent sub-pixels may be prevented via the stem disposed to overlap the first trench in the vertical direction.

Accordingly, according to an embodiment of the present disclosure, the generation of both the lateral leakage current and the forward leakage current that may occur due to short-circuits between adjacent ones of the plurality of charge generation layers may be reduced.

In addition, according to an embodiment of the present disclosure, the unwanted sub-pixels may be prevented from emitting light together, thereby preventing a decrease in color gamut and preventing image distortion to provide excellent image information.

Accordingly, according to an embodiment of the present disclosure, the high color gamut and high luminance of the display panel and the display device may be implemented, such that power consumption of the display panel and the display device may be reduced to implement a low power display panel and a lower power display device.

Effects of the present disclosure are not limited to the effects mentioned above, and other effects not mentioned will be clearly understood by those skilled in the art from the description as set forth below. In addition to the above effects, specific effects of the present disclosure are described together while describing specific details for carrying out the present disclosure.

### BRIEF DESCRIPTION OF THE SEVERAL VIEWS OF THE DRAWINGS

FIG. 1 is a schematic plan view of a display device.

FIG. 2 is a plan view of some pixels according to an embodiment.

FIG. 3 illustrates a first trench defined between adjacent sub-pixels.

FIG. 4 illustrates a structure according to an embodiment disposed on the first trench and extending along the first trench.

FIG. 5 is a plan view of a partial area in which the structure according to an embodiment is disposed on the first trench and extends along the first trench.

FIG. 6 is a cross-sectional view as taken along a line I-I′ of FIG. 5.

FIG. 7 illustrates a detailed stack structure of a light-emitting layer including a plurality of stacks according to an embodiment.

FIG. 8 is a cross-sectional view as taken along a line II-II′ of FIG. 5.

FIGS. 9 and 10 are cross-sectional views as taken along a line III-III′ of FIG. 5 according to another embodiment.

FIG. 11 is a process cross-sectional view illustrating a process of forming a second trench defined by a structure.

FIG. 12 is a plan view of some pixels according to another embodiment.

FIG. 13 illustrates a structure according to another embodiment disposed on the first trench and extending along the first trench.

FIG. 14 is a plan view of a partial area in which the structure according to another embodiment of the present disclosure is disposed on the first trench and extends along the first trench.

FIG. 15 is a cross-sectional view as taken along a line I-I′ of FIG. 14.

FIG. 16 is a cross-sectional view as taken along a line II-II′ of FIG. 14.

FIGS. 17 to 19 are cross-sectional views as taken along a line III-III′ of FIG. 14 according to another embodiment.

FIG. 20 is a schematic perspective view of a head-mounted display apparatus including a display device according to an embodiment of the present disclosure.

FIG. 21 is a top view illustrating a head-mounted display apparatus implementing virtual reality.

FIG. 22 is a side view illustrating a head-mounted display apparatus implementing augmented reality.

### DETAILED DESCRIPTION

Advantages and features of the present disclosure, and a method of achieving the advantages and features will become apparent with reference to embodiments described below in detail together with the accompanying drawings. However, the present disclosure is not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure and the appended claims are not limited by the disclosure. A shape, a size, a ratio, an angle, a number, etc., disclosed in the drawings for illustrating embodiments of the present disclosure are illustrative, and the present disclosure is not limited thereto. The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements may modify an entirety of the list of elements and may not modify the individual elements of the list. In interpretation of numerical values, an error or tolerance therein may occur even when there is no explicit description thereof. In addition, it will also be understood that when a first element or layer is referred to as being present “on” a second element or layer, the first element may be disposed directly on the second element or may be disposed indirectly on the second element with a third element or layer being disposed between the first and second elements or layers. It will be understood that when a first element or layer is referred to as being “connected to”, or “coupled to” a second element or layer, the first element may be directly connected to or coupled to the second element or layer, or one or more intervening elements or layers may be present therebetween. In addition, it will also be understood that when an element or layer is referred to as being “between” two elements or layers, it may be the only element or layer between the two elements or layers, or one or more intervening elements or layers may also be present therebetween. Further, as used herein, when a layer, film, area, plate, or the like is disposed “on” or “on a top” of another layer, film, area, plate, or the like, the former may directly contact the latter or still another layer, film, area, plate, or the like may be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, area, plate, or the like, the former may directly contact the latter or still another layer, film, area, plate, or the like may be disposed between the former and the latter. As used herein, when a layer, film, area, plate, or the like is directly disposed “below” or “under” another layer, film, area, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved. It will be understood that, although the terms “first”, “second”, “third”, and so on may be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

When an embodiment may be implemented differently, functions or operations specified within a specific block may be performed in a different order from an order specified in a flowchart. For example, two consecutive blocks may actually be performed substantially simultaneously, or the blocks may be performed in a reverse order depending on related functions or operations. The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, “embodiments,” “examples,” “aspects, etc., should not be construed such that any aspect or design as described is superior to or advantageous over other aspects or designs. Further, the term ‘or’ means ‘inclusive or’ rather than ‘exclusive or’. That is, unless otherwise stated or clear from the context, the expression that ‘x uses a or b’ means one of natural inclusive permutations.

The terms used in the description as set forth below have been selected as being general and universal in the related technical field. However, there may be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term may be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions. In description of flow of a signal, for example, when a signal is delivered from a node A to a node B, this may include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified. As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure may work functionally.

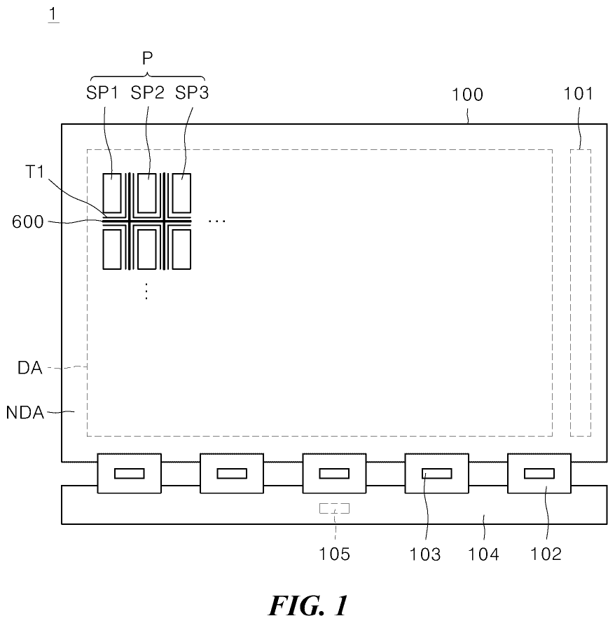

Hereinafter, a display panel and a display device according to an embodiment of the present disclosure will be described in detail with reference to FIG. 1. An example in which the display device 1 described below embodied as an organic electroluminescence display device (Organic Light Emitting Diodes Display Device) is described below. However, embodiments of the present disclosure are not limited thereto.

The display device 1 may include a substrate 100 including a display area DA and a non-display area NDA surrounding a periphery of the display area DA. The display device 1 may include the substrate 100, a source driver integrated circuit (IC) 103, a flexible film 102, a circuit board 104, and a timing controller 105.

The substrate 100 may be made of glass or plastic such as polyimide. However, embodiments of the present disclosure are not limited thereto, and the substrate 100 may be made of a semiconductor material such as a silicon wafer.

The display area DA on the substrate 100 may include a plurality of sub-pixels SP1, SP2, and SP3 respectively formed in intersection areas in which a plurality of data lines extending in a first direction and a plurality of gate lines extending in a second direction intersecting the first direction intersect each other. The first direction described herein may be an X-axis direction, the second direction described herein may be a Y-axis direction, and a Z-axis direction described herein may be a direction perpendicular to the X-axis and the Y-axis. In addition, in the present disclosure, an example in which one pixel P is composed of the first sub-pixel SP1, the second sub-pixel SP2, and the third sub-pixel SP3 will be described. However, embodiments of the present disclosure are not limited thereto, and additional sub-pixels may be further included in one pixel P.

The sub-pixels SP1, SP2, and SP3 may be implemented to emit light of the same color, such as white light, or may be implemented to emit light of different colors, such as red, green, and blue light, respectively. Hereinafter, an embodiment in which the first sub-pixel SP1 emits red light, the second sub-pixel SP2 emits green light, and the third sub-pixel SP3 emits blue light will be described. The plurality of sub-pixels SP1, SP2, and SP3 may be arranged in a matrix form arranged in a plurality of rows and columns.

A gate driver 101 positioned at one side or each of both opposing sides of the display area DA may be disposed in the non-display area NDA and on the substrate 100. The gate driver 101 may be implemented in a Gate-in-panel (GIP) manner. The gate driver 101 may supply gate signals to the gate lines GL according to a gate control signal GCS input from the timing controller 105.

The source driver integrated circuit 103 may receive digital video data and a source control signal from the timing controller 105. The source driver integrated circuit 103 may convert the digital video data into analog data voltages according to a source control signal and supply the analog data voltages to the data lines DL. The source driver integrated circuit 103 may be manufactured as a driving chip in a chip on film (COF) or chip on plastic (COP) manner and may be mounted on a plurality of flexible films 102. The circuit board 104 may be attached to the plurality of flexible films 102. A plurality of circuits implemented as driving chips such as the timing controller 105 may be mounted on the circuit board 104.

The timing controller 105 may receive the digital video data and a timing signal from an external system board via a cable of the circuit board 104. The timing controller 105 may supply the gate control signal for controlling the operation timing of the gate driver 101 and the source control signal for controlling the source driver integrated circuits 103 based on the timing signal.

In one example, the first trench T1 and the structure 600 formed on the first trench T1 may be disposed between the sub-pixels SP. Hereinafter, the plurality of sub-pixels P, the first trench T1 formed therebetween, and the structure 600 formed on the first trench will be described in detail.

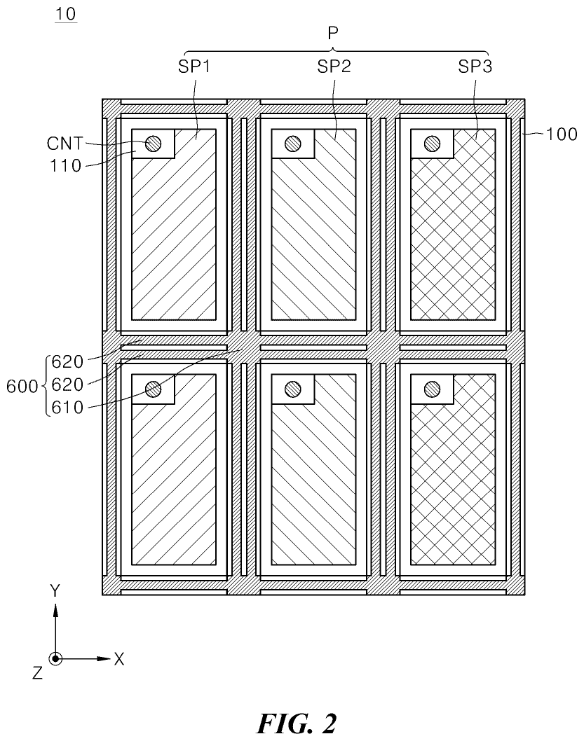

Referring to FIG. 2, FIG. 2 is a plan view in which two pixels P adjacent to each other are enlarged, and is illustrated based on a 2×3 matrix structure. Each pixel P may include a first sub-pixel P, a second sub-pixel SP2, and a third sub-pixel SP3.

A circuit area 110 may be disposed in each sub-pixel included in the display panel 10, and the circuit area 110 may be electrically connected to a light-emitting element layer via a contact CNT. For example, the circuit area 110 may include various signal lines, and a circuit element including a thin-film transistor, a capacitor, etc. The thin-film transistor may include a switching thin-film transistor, a driving thin-film transistor, a sensing thin-film transistor, etc. However, embodiments of the present disclosure are not limited thereto, and the thin-film transistor may include a Complementary Metal Oxide Semiconductor (CMOS) transistor. A connection structure between the circuit area 110 and the light-emitting element layer via the contact CNT will be described later.

The structure 600 may be disposed between ones of a plurality of sub-pixels SP adjacent to each other. The structure 600 may include an anchor 610 and a pair of stems 620 supported by the anchor 610 and extending in one direction. The anchor 610 may be disposed at a point where the first direction and the second direction intersect with each other. Accordingly, the anchor 610 may be disposed at each of corners where four sub-pixels are in contact with each other based on the arrangement structure of the sub-pixels of the 2×2 matrix. The pair of stems 620 may extend from the anchor 610 while being disposed between ones of a plurality of sub-pixels SP adjacent to each other in each of the first direction and the second direction. Each stem may extend in each of the first direction and the second direction in the plan view of the display device. The pair of stems 620 may extend so as to connect adjacent anchors 610 to each other. The pair of stems 620 extending in the same direction may be spaced apart from each other by a predetermined spacing and may extend parallel to each other.

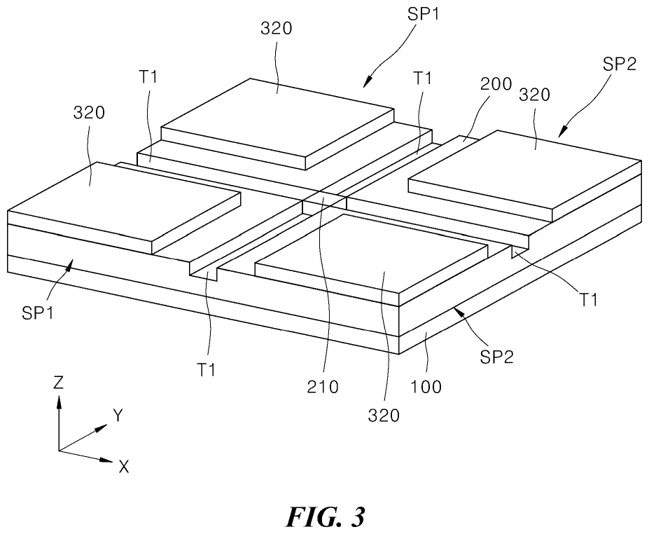

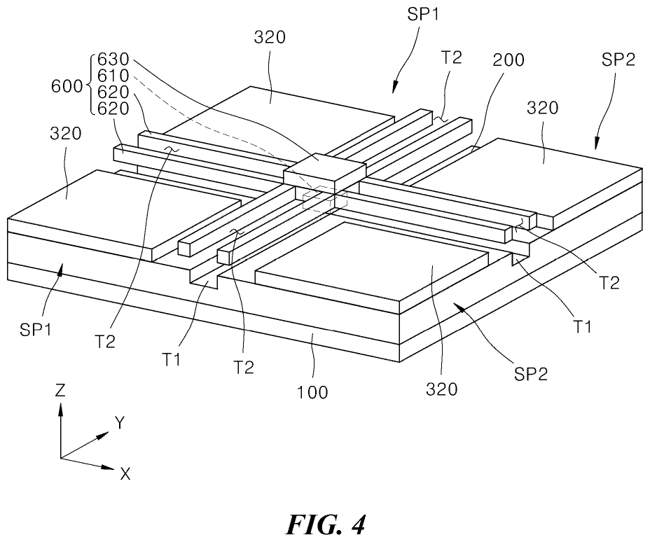

Hereinafter, an arrangement structure of the structure 600 will be described in more detail with further reference to FIGS. 3 to 4. FIGS. 3 and 4 are illustrated based on a 2×2 matrix sub-pixel arrangement structure on the substrate 100.

An insulating layer 200 may be disposed on the substrate 100. For example, the insulating layer 200 may be formed as an organic film made of acryl resin, epoxy resin, phenolic resin, polyamide resin, polyimide resin, or the like. However, embodiments of the present disclosure are not limited thereto, and the insulating layer 200 may be formed as an inorganic film made of silicon nitride, aluminum nitride, zirconium nitride, titanium nitride, hafnium nitride, tantalum nitride, silicon oxide, aluminum oxide, or titanium oxide.

A first electrode 320 may be disposed on the insulating layer 200 and in an area corresponding to each sub-pixel. For example, the first electrode 320 may be electrically connected to the light-emitting element layer to be described later, and may function as an anode electrode.

FIG. 3 illustrates the substrate 100 in which the first trench T1 is formed in a state in which the structure 600 is not disposed on the first trench. The first trench T1 may be formed between ones of the plurality of sub-pixels SP adjacent to each other. The first trench T1 may be formed by removing a partial area of the insulating layer 200. Accordingly, the first trench T1 may be formed in a form of a concave groove recessed downwardly into the insulating layer 200 so as to have a predetermined left-right width and a predefined vertical length. The first trench T1 may extend in the first direction DR1 and the second direction DR2 so as to pass through a boundary between ones of a plurality of sub-pixels SP adjacent to each other. However, a portion of the insulating layer 200 is not removed at a corner where the four sub-pixels SP are adjacent to each other as a point where the first direction and the second direction intersect with each other. This remaining portion of the insulating layer 200 at the corner may act as a support 210. Thus, the first trench T1 is not formed in the corner. That is, the support 210 may be formed in an area where the first trench T1 extending in the first direction DR1 intersects the first trench T1 extending in the second direction DR2. Accordingly, the first trench T1 extending along each of the first direction DR1 and the second direction DR2 may be discontinuous or broken due to the support 210.

FIG. 4 illustrates that the structure 600 is additionally disposed on an area of the substrate 100 in which the first trench T1 is formed. The structure 600 may be spaced apart from the first trench T1 by a predetermined distance and may extend along the first trench T1 and may be disposed on the first trench T1. The structure 600 may include the anchor 610 supported by the support 210 as the remaining portion of the insulating layer 200, and the stem 620 extending from the anchor 610 along each of the first direction and the second direction.

The anchor 610 may serve as a pillar supporting an overall shape of the structure 600. Since the anchor 610 is disposed to be in contact with the support 210 as the portion of the insulating layer 200 while the anchor is not spaced apart from the support, the support 210 may directly support the anchor 610 thereon. However, embodiments of the present disclosure are not limited thereto. For example, an additional support layer may be disposed between the support 210 as the portion of the insulating layer 200 and the anchor 610, so that the support 210 may indirectly support the anchor 610 while the additional support layer is interposed therebetween. In an example, the additional support layer may be a fence 330, and the fence 330 will be described later.

The stem 620 may extend from the anchor 610 along each of the first direction and the second direction. In this case, the pair of stems 620 may be spaced apart from each other by a predetermined distance in a first horizontal direction and extend in parallel with each other and along the first direction. Further, the pair of stems 620 may be spaced apart from each other by a predetermined distance in a second horizontal direction and extend in parallel each other and along the second direction. The stems 620 extending as described above may extend in the same direction as the direction in which the first trench T1 extends, and may be disposed to be spaced apart from the insulating layer 200 by a predetermined distance in the vertical direction. That is, the structure 600 may have a construction that the anchor 610 thereof is supported on the insulating layer 200. Thus, even when the stem 620 is spaced apart from the insulating layer 200 by a predetermined distance in the vertical direction, the stem 620 may be reliably supported.

A second trench T2 may be formed between the pair of stems 620 extending in the same direction. The second trench T2 may be formed to have a hole shape extending in the vertical direction, and a vertical length of the second trench T2 may be set to be the same as the vertical length of the stem 620. Therefore, the second trench T2 may be formed to extend in the same direction as the extension direction of the first trench T1 in the plan view, and may be disposed to overlap the first trench T1 in the vertical direction.

Since the pair of stems 620 are disposed to be spaced apart from the first trench T1 by a predetermined distance in the vertical direction, the second trench T2 defined between the pair of stems 620 may also be disposed to be spaced apart from the first trench T1 by a predetermined distance in the vertical direction. That is, the first trench T1 may have a shape that is opened upwardly and closed downwardly, while the second trench T2 may have a shape that is opened both upwardly and downwardly.

As described above, the anchor 610 may be formed to protrude downwardly beyond the stem 620, so that the stem 620 may be disposed to be spaced apart from the insulating layer 200 by the predetermined distance. The anchor 610 may be formed to protrude further upwardly beyond the stem 620. As described above, a partial area of the anchor 610 protruding upwardly beyond the stem 620 may be referred to as a protrusion 630. An area size in the plan view of the protrusion 630 of the anchor 610 may be larger than an area size in the plan view of a portion of the anchor 610 disposed under the protrusion 630. In addition, the protrusion 630 may be formed to have a larger area size in the plan view than that of the support 210 supporting a lower end of the anchor 610. Accordingly, the portion of the anchor 610 disposed under the protrusion 630 and the support 210 may constitute an undercut structure. However, embodiments of the present disclosure are not limited thereto, and the area size in the plan view of the protrusion 630 of the anchor 610 may be equal to the area size in the plan view of the portion of the anchor 610 disposed under the protrusion 630 and serving as a support pillar of the structure 600.

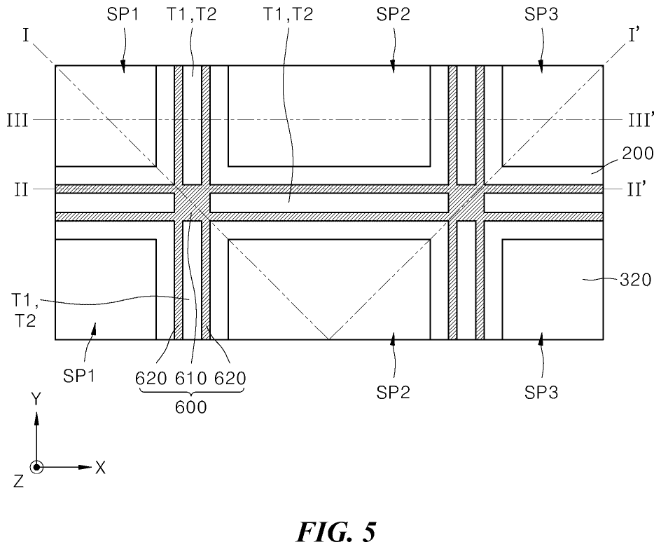

Hereinafter, referring to FIGS. 5 to 10, a cross-sectional structure in a state in which the structure 600 is formed on the first trench T1 will be described in more detail.

Hereinafter, a OLEDoS (OLED on Si wafer) structure in which the circuit area 110 including a complementary metal oxide semiconductor (CMOS) transistor is disposed on the substrate 100 as a silicon wafer, and a light-emitting element layer 400 including an organic light-emitting element is disposed on the circuit area 110 will be described by way of example. However, embodiments of the present disclosure are not limited thereto.

The circuit area 110 may be disposed on the substrate 100. The substrate 100 may be embodied as a single crystal silicon wafer formed by growing single crystal silicon (Si). However, embodiments of the present disclosure are not limited thereto, and the substrate 100 may be a wafer made of various semiconductor materials.

The circuit area 110 may include an active area formation area 117, a circuit area insulating layer 118, and a transistor Tr formed in the active area formation area 117 and the circuit area insulating layer 118. A separate transistor Tr may be disposed in an area corresponding to each of the sub-pixels SP1, SP2, and SP3, and the arrangement structure of the transistor as described below will be described based on one sub-pixel. However, the same arrangement structure may be applied to each of other sub-pixels.

The transistor Tr may be disposed on the substrate 100. The transistor Tr may include a source area 111a, a drain area 111b, a source electrode 113a, a drain electrode 113b, and a gate electrode 115.

The source area 111a and the drain area 111b may be formed on the substrate 100 so as to be spaced apart from each other by a predetermined distance in the horizontal direction. For example, the source area 111a and the drain area 111b may be formed by doping an impurity into the substrate 100. A channel area 111c not doped with impurities may be formed between the source area 111a and the drain area 111b. An area in which the source area 111a and the drain area 111b are formed in the substrate 100 may be referred to as the active area formation area 117. Therefore, the active area formation area 117 disposed on the substrate 100 may be an area that is not physically separated from the substrate 100 but may be an area that is conceptionally separated therefrom.

The circuit area insulating layer 118 may be formed on the substrate 100. The circuit area insulating layer 118 may be formed as a single layer made of an inorganic material such as silicon nitride (SiNx) or silicon oxide (SiOx) or a plurality of layers made thereof. However, embodiments of the present disclosure are not limited thereto, and the circuit area insulating layer 118 may be formed as a single layer made of an organic material such as photoacryl or a plurality of layers made thereof.

The source electrode 113a and the drain electrode 113b electrically connected to the source area 111a and the drain area 111b, respectively, may be formed in the circuit area insulating layer 118. The source electrode 113a and the drain electrode 113b may be connected to the source area 111a and the drain area 111a via first contact holes 112b, respectively. In addition, the gate electrode 115 positioned to overlap the channel area 111c in the vertical direction may be disposed in the circuit area insulating layer 118. A gate insulating layer 114 may be disposed between the gate electrode 115 and the channel area 111c. The gate insulating layer 114 may be formed as a single layer made of an inorganic material such as silicon nitride (SiNx) or silicon oxide (SiOx) or a plurality of layers made thereof. However, embodiments of the present disclosure are not limited thereto. Each of the source electrode 113a, the drain electrode 113b, and the gate electrode 115 may be made of a metal material, and for example, may be formed as a single layer or multiple layers made of one selected from the group consisting of chromium (Cr), aluminum (Al), silver (Ag), copper (Cu), magnesium (Mg), molybdenum (Mo), and titanium (Ti) or alloys thereof. However, embodiments of the present disclosure are not limited thereto.

A connection line 116 may be formed on the transistor Tr formed as described above, and the connection line 116 may be electrically connected to the drain electrode 113b via a second contact hole 112b formed in the circuit area insulating layer 118. The insulating layer 200 may be formed on the connection line 116. The insulating layer 200 may be made of the same material as that of the circuit area insulating layer 118. However, embodiments of the present disclosure are not limited thereto.

The first electrode 320 may be disposed on the insulating layer 200. In addition, a reflective electrode 310 may be additionally disposed between the first electrode 320 and the insulating layer 200. The reflective electrode 310 may be made of a metal material including silver (Ag) or silver (Ag), and may reflect light emitted from the light-emitting element layer 400 therefrom toward the second electrode 340 to increase light efficiency.

The first electrodes 320 respectively disposed in the sub-pixels SP adjacent to each other may be disposed to be spaced apart from each other. The reflective electrodes 310 respectively disposed in the sub-pixels SP adjacent to each other may be disposed to be spaced apart from each other. The fence 330 may be disposed on the first electrode 320. The fence 330 may be formed to cover a side surface and an edge of an upper surface of the first electrode 320, thereby preventing current from being concentrated to a side end of the first electrode 320. The fence 330 may be formed as a single layer made of an inorganic material such as silicon nitride (SiNx) or silicon oxide (SiOx) or a plurality of layers made thereof. However, embodiments of the present disclosure are not limited thereto. The fence 330 may be referred to as a bank layer.

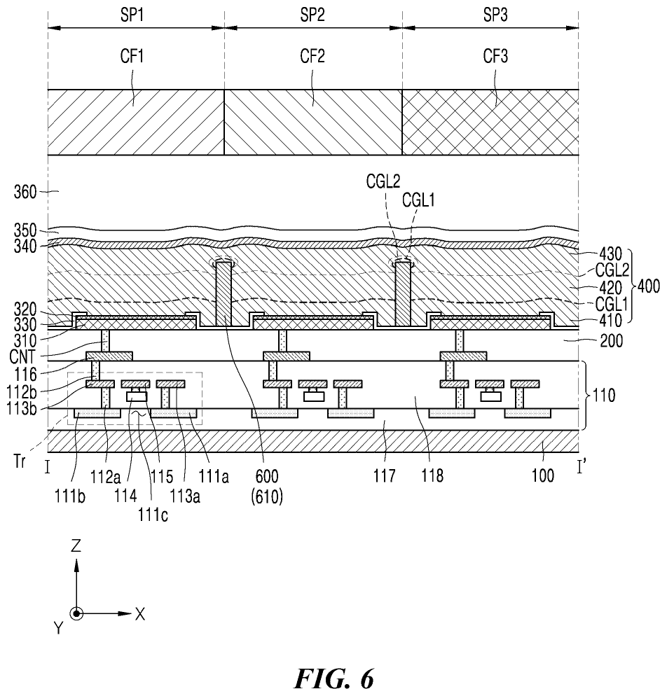

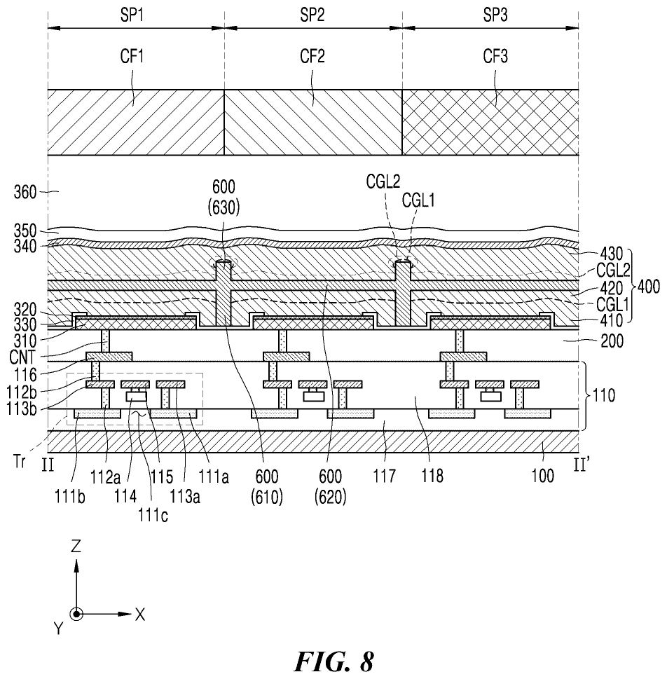

Referring to FIGS. 6 and 8, in an area in which the anchor 610 of the structure 600 is disposed, the fence 330 may continuously extend so as to cover a side surface and an edge of an upper surface of each of the first electrodes 320 respectively disposed in the sub-pixels SP adjacent to each other. A lower end of the anchor 610 positioned at a boundary between adjacent sub-pixels may be supported on the fence 330.

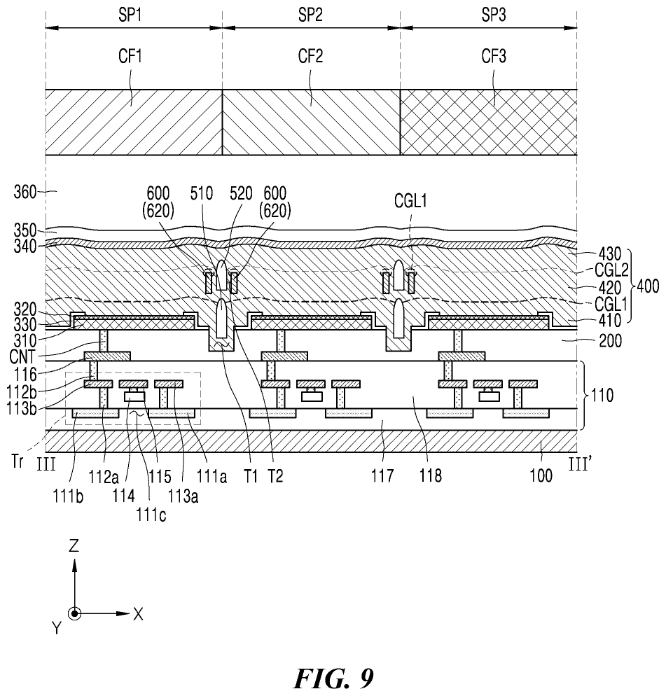

Referring to FIG. 9, in an area in which the stem 620 of the structure 600 is disposed, the fence 330 may not be formed in an area in which the first trench T1 is formed. Accordingly, the fence 330 may be discontinuous or broken in the area in which the first trench T1 is formed while the fence 330 covers a side surface and an edge of an upper surface of each of the first electrodes 320 respectively disposed in the sub-pixels SP adjacent to each other. That is, the first trench T1 and the fence 330 may be formed so as not to overlap each other in the vertical direction. Therefore, the first trench T1 may be formed between a pair of fences 330 respectively disposed in sub-pixels SP adjacent to each other.

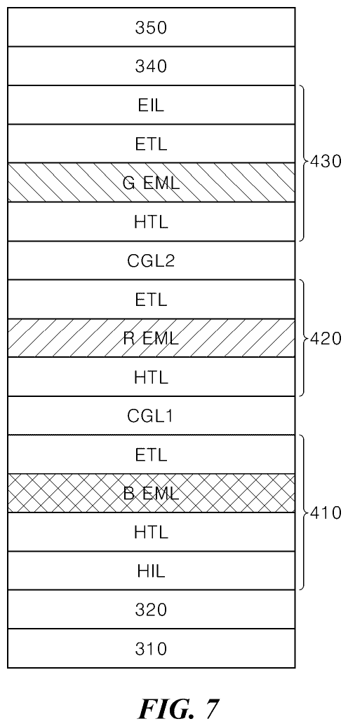

The light-emitting element layer 400 may be disposed on the first electrode 320. An embodiment in which the light-emitting element layer 400 has a tandem structure in which three stacks are vertically arranged will be described by way of example. However, embodiments of the present disclosure are not limited thereto, and the light-emitting element layer 400 may have a tandem structure in which four or more stacks are vertically arranged. Referring further to FIG. 7, the light-emitting element layer 400 including a first stack 410, a first charge generation layer CGL1, a second stack 420, a second charge generation layer CGL2, and a third stack 430 sequentially stacked vertically may be disposed on the first electrode 320. The second electrode 340 may be disposed on the light-emitting element layer 400. When a further stack is added to a structure in which four or more stacks are vertically arranged in this way, a further charge generation layer may be additionally stacked.

For example, the first stack 410 may include a hole injection layer HIL, a hole transport layer HTL, a first organic light-emitting layer B EML, and an electron transport layer ETL, the second stack 420 may include a hole transport layer HTL, a second organic light-emitting layer R EML, and an electron transport layer ETL, and the third stack 430 may include a hole transport layer HTL, a third organic light-emitting layer G EML, an electron transport layer ETL, and an electron injection layer EIL. However, embodiments of the present disclosure are not limited thereto. For example, the first organic light-emitting layer B EML may be a blue light-emitting layer, the second organic light-emitting layer R EML may be a red light-emitting layer, and the third organic light-emitting layer G EML may be a green light-emitting layer. However, the stacking order of the first organic light-emitting layer B EML, the second organic light-emitting layer R EML, and the third organic light-emitting layer G EML, that is, a position of the stack including each of the organic light-emitting layers may vary. The light-emitting element layer 400 configured as described above may emit white light.

The hole injection layer HIL may serve to efficiently inject holes from the first electrode 320 into the organic material layer. The hole transport layer HTL may serve to help holes migrate to the organic light-emitting layer EML. The organic light-emitting layer EML is a layer that substantially emits light, and holes and electrons may be recombined with each other therein to emit light. The electron transport layer ETL may serve to inject electrons such that the electrons migrate to the organic light-emitting layer EML. The electron injection layer EIL may serve to efficiently inject electrons from the second electrode 340 into the organic material layer.

The first charge generation layer CGL1 may be disposed between the first stack 410 and the second stack 420 and may supply electric charges to the first stack 410 and the second stack 420 to adjust a charge balance between the first stack 410 and the second stack 420. In addition, the second charge generation layer CGL2 may be disposed between the second stack 420 and the third stack 430 and may supply electric charges to the second stack 420 and the third stack 430 to adjust charge balance between the second stack 420 and the third stack 430. The first charge generation layer CGL1 may be formed as a single layer. However, embodiments of the present disclosure are not limited thereto, and the first charge generation layer CGL1 may be formed as a plurality of layers including a first N-type charge generation layer and a first P-type charge generation layer. Likewise, the second charge generation layer CGL2 may be formed as a single layer. However, embodiments of the present disclosure are not limited thereto, and the second charge generation layer CGL2 may be formed as a plurality of layers including a second N-type charge generation layer and a second P-type charge generation layer.

Each of the layers included in the light-emitting element layer 400 may be made of an organic material. In this case, each of the first charge generation layer CGL1 and the second charge generation layer CGL2 may be formed as an organic material layer, or as an organic material layer into which a material such as a metal or a metal oxide is doped. However, embodiments of the present disclosure are not limited thereto.

The second electrode 340 may be disposed on the light-emitting element layer 400, and the second electrode 340 may function as a cathode electrode. The second electrode 340 may be formed across an entire surface of the substrate 100 so as to be commonly connected to all of the light-emitting element layers 400 formed in all pixels P. Accordingly, the second electrode 340 may be referred to as a common electrode. In a top emission type display panel 10 in which light emitted from the light-emitting element layer 400 is emitted upwardly, the second electrode 340 may be made of a transparent conductive material such as indium tin oxide (ITO) or indium zinc oxide (IZO).

A capping layer 350 and an encapsulation layer 360 may be stacked on the second electrode 340. Each of the capping layer 350 and the encapsulation layer 360 may include an inorganic material, an organic material, or a mixture of an inorganic material and an organic material, and may be formed as a single layer or multiple layers.

A color filter CF1, CF2, and CF3 may be disposed on the encapsulation layer 360. For example, the color filter may include a red first color filter CF1 provided in the first sub-pixel SP1, a green second color filter CF2 provided in the second sub-pixel SP2, and a blue third color filter CF3 provided in the third sub-pixel SP3. Accordingly, in the first sub-pixel SP1, white light emitted from the light-emitting element layer 400 passes through the first color filter CF such that only red light is emitted out thereof. In the second sub-pixel SP2, white light emitted from the light-emitting element layer 400 passes through the second color filter CF2 such that only green light is emitted out thereof. In the third sub-pixel SP3, white light emitted from the light-emitting element layer 400 passes through the third color filter CF3 such that only blue light is emitted out thereof.

Hereinafter, a detailed arrangement structure of the structure 600 in the display panel 10 having such a stacked structure will be described.

Referring to FIG. 6, the structure 600 may prevent an electrical connection between the first charge generation layers CGL1 respectively disposed in adjacent sub-pixels, and an electrical connection between the second charge generation layers CGL2 respectively disposed in adjacent sub-pixels. More specifically, a lower end of the anchor 610 of the structure 600 may be supported on the fence 330 disposed on the insulating layer 200, and the structure 600 may extend upwardly so as to extend through the first charge generation layer CGL1 and the second charge generation layer CGL2. That is, a vertical level of an upper end of the anchor 610 may be higher than a vertical level of an upper surface of the second charge generation layer CGL2. However, in a state in which the structure 600 has been formed, the first charge generation layer CGL1 and the second charge generation layer CGL2 may be sequentially deposited thereon in terms of the formation process. Thus, a portion of the first charge generation layer CGL1 and a portion of the second charge generation layer CGL2 may be sequentially stacked on the upper end of the anchor 610. However, each of the portion of the first charge generation layer CGL1 and the portion of the second charge generation layer CGL2 formed on the upper end of the anchor 610 may not extend continuously but may be disconnected from each of the first charge generation layer CGL1 and the second charge generation layer CGL2 disposed in the sub-pixel due to a difference between the vertical level of the top surface of the anchor 610 extending upwardly through the second charge generation layer CGL2 and the vertical level of the upper surface of the second charge generation layer CGL2. As described above, the anchor 610 of the structure 600 may not only prevent the connection between the first charge generation layers CGL1 respectively disposed in the sub-pixels SP disposed adjacent to each other, but also may prevent the connection between the second charge generation layers CGL2 respectively disposed in the sub-pixels SP disposed adjacent to each other.

Referring to FIG. 8, the stem 620 may be disposed between the first charge generation layer CGL1 and the second charge generation layer CGL2. In this case, it may be identified that each of the first charge generation layer CGL1 and the second charge generation layer CGL2 are discontinuous in a horizontal manner due to the protrusion 630 protruding upwardly from the anchor 610. Further, the first charge generation layer CGL1 and the second charge generation layer CGL2 are disconnected from each other via the stem 620 in the vertical manner. That is, according to the present disclosure, the protrusion 630 protruding upwardly from the anchor 610 may prevent the first charge generation layers CGL1 respectively disposed in the sub-pixels adjacent to each other from being connected to each other and may prevent the second charge generation layers CGL2 respectively disposed in the sub-pixels adjacent to each other from being connected to each other in the area where the anchor 610 is disposed. Further, the stem 620 extending from the anchor in the horizontal manner may prevent the first charge generation layer CGL1 and the second charge generation layer CGL2 arranged in the vertical manner from being connected to each other.

Referring to FIG. 9, a first trench T1 may be formed at a boundary between the sub-pixels SP adjacent to each other. The first trench T1 may be defined by the pair of fences 330 disposed on the insulating layer 200 and respectively disposed on both opposing sides of the first trench T1 and on top of the first trench T1. The second trench T2 may be defined by the pair of stems 620 and may be formed on top of the first trench T1. The second trench T2 may refer to the spacing between the pair of stems 620 disposed to be spaced apart from each other in the horizontal direction. In this case, the first trench T1 may be disposed to overlap the second trench T2 in the vertical direction.

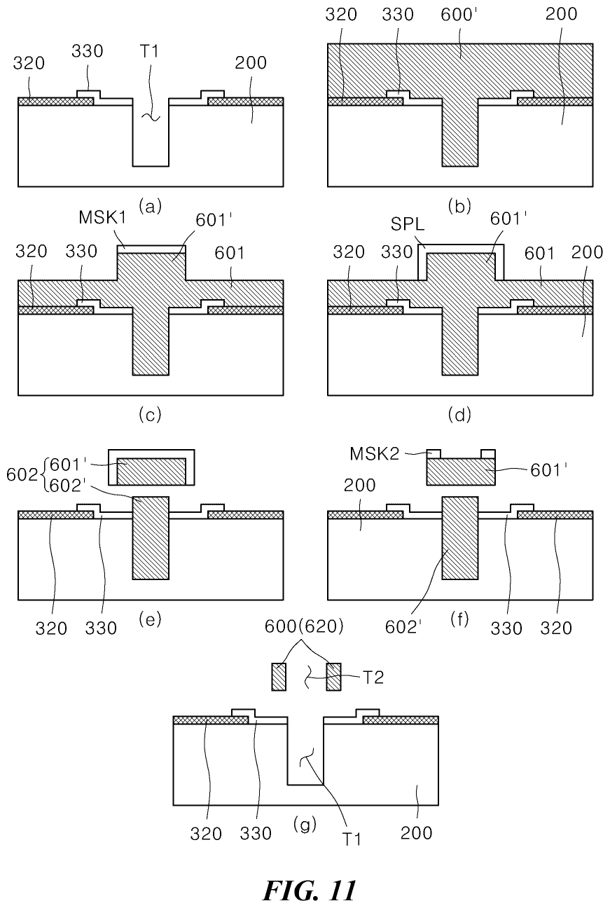

Referring to FIG. 11, a process of forming the first trench T1 and the second trench T2 will be described.

Step (a) is a step of forming the first trench T1 in the insulating layer 200. The first trench T1 may be formed by etching a portion of the insulating layer 200 in an area opened by the fence 330 disposed on the insulating layer 200 so as to cover the side end of the first electrode 320. As the insulating layer 200 is etched to a predetermined depth, the first trench T1 may be formed in a shape of a concave groover recessed to have a predetermined vertical length. A left-right width of the first trench T1 may correspond to a spacing between the fences 330 adjacent to each other. For example, the first trench T1 may be formed in an accurate depth and shape using a plasma etching method.

Step (b) is a step of depositing a structure material 600′ as a material constituting the structure on the insulating layer 200 in which the first trench T1 has been formed. The structure material 600′ may include one of polysilicon or oxide. However, embodiments of the present disclosure are not limited thereto. In this case, the deposition process may be performed using a chemical vapor deposition (CVD) method or a sputtering method.

Step (c) is a step of patterning the structure material 600′ deposited in the step (b). After the structure material 600′ has been deposited, a first mask MSK1 may be disposed on the structure material 600′ in an area overlapping the first trench T1 in the vertical direction. A size of the first mask MSK1 may correspond to a distance between both opposing outer side ends of a combination of the pair of stems 620 to be formed. After the first mask MSK1 has been formed as described above, a portion of the structure material 600′ in an area other than the first mask MSK1 may be patterned to be etched by a predetermined thickness via the photolithography process and the etching process, thereby forming a first patterning structure 601 having a desired pattern. As a thickness of the portion of the structure material 600′ in the area where the first mask MSK1 is not disposed is reduced via the step (c), a step structure 601′ having a step may be formed in the area where the first mask MSK1 is disposed.

Step (d) is a step in which the first mask MSK1 is removed, and a sidewall protective layer SPL surrounding an upper surface and a side surface of the step structure 601′ of the first patterning structure 601 formed via the step (c) is deposited. The sidewall protective layer SPL may be made of a material having a high selectivity, such as an oxide, an organic material, or C4F8, etc., having a high dielectric constant and heat resistance, such as aluminum oxide and hafnium oxide used in an atomic layer deposition (ALD) process.

Step (e) is a step of performing deep ion etching (DIE) on the first patterning structure 601. In the first patterning structure 601 on which the sidewall protection layer SPL is formed in the step (d), an entirety of the remaining portion of the structure material 600′ except for only the stepped structure 601′ and a trench structure 602′ may be removed via the deep ion etching process. The deep ion etching may deeply remove the first patterning structure 601 using high energy ions. Accordingly, the stepped structure 601′ protected by the sidewall protection layer SPL may not be removed, and the trench structure 602′ filling the first trench T1 may not be removed. In this case, a portion of the structure material 600′ between the stepped structure 601′ and the trench structure 602′ may be removed, and thus the stepped structure 601′ and the trench structure 602′ may be formed to be spaced apart from each other. In this way, the first patterning structure 601 may be converted into a second patterning structure 602 including the stepped structure 601′ and the trench structure 602′ spaced from each other.

Step (f) is a step of forming a second mask MSK2 for patterning the second patterning structure 602. The sidewall protective layer SPL protecting the stepped portion of structure 600 may be removed, and the second mask MSK2 may be disposed on the stepped portion of structure 600. The second mask MSK2 is a mask having a pattern for forming the stem 620. Therefore, the second mask MSK 2 may have a pattern that is disposed on each of both opposing edges of an upper surface of the stepped portion of structure 600, but does not overlap the first trench T1 in the vertical direction.

Step (g) is a step of patterning the second patterning structure 602 and removing the second mask MSK2. When the second patterning structure 602 is etched via the photolithography process and the etching process, and the second mask MSK 2 is removed, the pair of stems 620 may be finally formed to be spaced apart from each other by a predetermined distance in the horizontal direction. The second trench T2 may be defined between the pair of stems 620. In this way, the first trench T1 and the second trench T2 may be formed to overlap each other in the vertical direction.

A first void 510 and a second void 520 may be formed in the first trench T1 and the second trench T2, respectively. The first void 510 may be disposed inside the first trench T1, and the second void 520 may be disposed inside the second trench T2 so as to overlap the first void 510 in the vertical direction.

The first void 510 may be formed in a following process. The light-emitting element layer 400 and the second electrode 340 may be formed on the insulating layer 200, the first electrode 320, and the fence 330. In this case, the light-emitting element layer 400 may be formed to cover an inner side surface and a lower surface of the first trench T1. In this case, an inner width of the first trench T1 may be formed to have a narrow width such that all layers constituting the light-emitting element layer 400 are not conformally deposited. Accordingly, at least a portion of the first stack 410 included in the light-emitting element layer 400 may be broken or discontinuous without being continuous in the first trench T1, and in some cases, a portion of the first stack 410 may extend continuously in the first trench T1.

The first charge generation layer CGL1 may be discontinuous or broken without being continuous inside the first trench T1 or on top of the first trench T1. In addition, the second stack 420 may extend continuously on top of the first trench T1, while a portion of the second stack 420 may be discontinuous or broken on top of the first trench T1. Accordingly, the first void 510 may be formed inside the light-emitting element layer 400 in the area overlapping the first trench T1, and the first void 510 may serve to disconnect the adjacent first charge generation layers CGL1 respectively disposed in adjacent ones of the plurality of sub-pixels from each other.

As described above, in a process of forming the light-emitting element layer 400 in the state in which the first trench T1 having the predetermined width has been formed, the first void 510 having a hollow shape may be formed inside the first trench T1, and the first void 510 may serve to disconnect the first charge generation layers CGL1 adjacent to each other horizontally from each other.

As described above, the second void 520 formed inside the second trench T2 may also be formed in the same manner as the above manner in which the first void 510 is formed inside the first trench T1.

The pair of stems 620 may serve the same role as the role of both opposing sidewalls defining the first trench T1. The pair of stems 620 may be disposed between the first charge generation layer CGL1 and the second charge generation layer CGL2 in the vertical direction. In addition, the pair of stems 620 may be disposed between the first stack 410 and the third stack 430 in the vertical direction, and may be disposed in the second stack 420.

The light-emitting element layer 400 formed on the second trench T2 defined between the pair of stems 620 may be formed to cover an inner side surface and a lower surface of the second trench T2. In this case, an inner width of the second trench T2 may be formed to have a narrow width such that all layers constituting the light-emitting element layer 400 are not conformally deposited.

Accordingly, at least a portion of the second stack 420 included in the light-emitting element layer 400 may be broken or discontinuous without being continuous in the second trench T2, and in some cases, a portion of the second stack 420 may extend continuously in the second trench T2.

The second charge generation layer CGL2 may be broken or discontinuous without being continuous inside the second trench T2 or on top of the second trench T2. In addition, the third stack 430 may extend continuously on top of the second trench T2, while a portion of the third stack 430 may be broken or discontinuous on top of the second trench T2. Accordingly, the second void 520 may be formed inside the light-emitting element layer 400 in an area overlapping the second trench T2, and the second void 520 may serve to disconnect the adjacent second charge generation layers CGL2 respectively disposed in adjacent ones of the plurality of sub-pixels from each other.

As described above, in the process of forming the light-emitting element layer 400 in the state in which the second trench T2 having a predetermined width has been formed, the second void 520 having a hollow shape may be formed in the second trench T2, and the second void 520 may serve to disconnect the second charge generation layers CGL2 adjacent to each other horizontally from each other. The broken portion of the second charge generation layer CGL2 may be stacked on an upper end of each of the pair of stems 620.

An inner width of the second trench T2 may be set to a width sized such that the second charge generation layer CGL2 is broken while the second electrode 340 extends continuously. In addition, the inner width of the second trench T2 may be set to a range sized such that the formation of the first void 510 and the second void 520 is smoothly achieved.

To this end, the inner width of the second trench T2 may be set to be substantially the same as the inner width of the first trench T1. However, the present disclosure is not limited thereto. For example, the inner width of the second trench T2 may be set to be greater than the inner width of the first trench T1. However, it may be preferable that a difference between the inner width of the first trench T1 and the inner width of the second trench T2 is not large.

In addition, a vertical length of the stem 620 is preferably set to be smaller than a vertical length of the second stack 420 so that the formation of the first void 510 based on the first trench T1 and the formation of the second void 520 based on the second trench T2 are smoothly achieved.

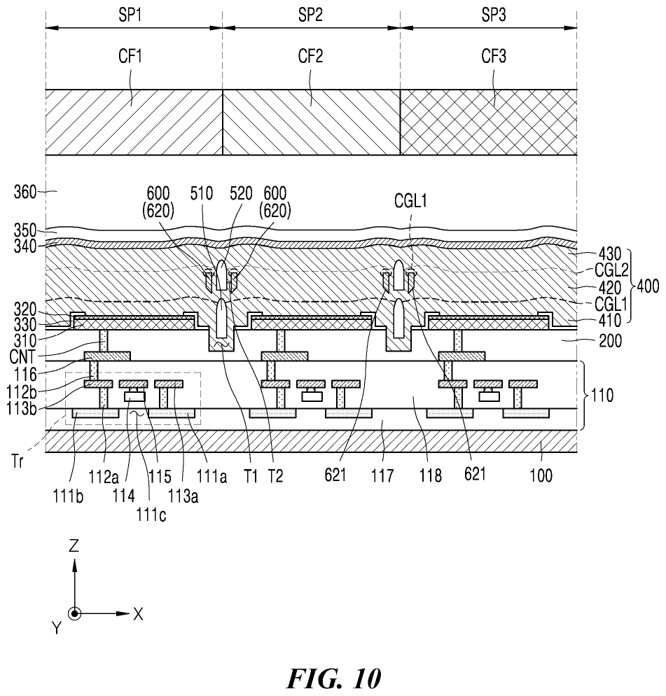

Referring to FIG. 10, in the present disclosure according to another embodiment, an outer side surface of a lower portion of each of the pair of stems 620 be an inclined surface 621 inclined downwardly toward a center of the first trench T1. When the lower end of the stem 620 is disposed adjacent to the first trench T1, in the process of depositing the light-emitting element layer 400 in the first trench T1 to form the first void 510, a deposition shadowing phenomenon may occur in which the lower end of the stem 620 interferes with the deposition. Therefore, according to the present disclosure, the outer side surface of the lower portion of the stem 620 may be the inclined surface 621, such that the deposition shadowing phenomenon on the first trench T1 which may be generated due to the lower portion of the stem 620 may be reduced, and thus the first void 510 may be smoothly formed in the first trench T1.

In the display panel and the display device according to the present disclosure described above, a short-circuit between the first charge generation layers CGL1 of the sub-pixels SPX adjacent to each other may be prevented due to the first trench T1 defined between adjacent ones of the plurality of sub-pixels SPX, and a short-circuit between the second charge generation layers CGL2 of the sub-pixels SPX adjacent to each other may be prevented due to the second trench T2.

That is, the first trench T1 may prevent the first charge generation layers CGL1 adjacent to each other in the horizontal direction from being connected to each other. The second trench T2 may prevent the second charge generation layers CGL2 adjacent to each other in the horizontal direction from being connected to each other. Accordingly, according to the present disclosure, the generation of the lateral leakage current that may occur due to the short-circuit between the charge generation layers of the sub-pixels adjacent to each other may be suppressed.

In one example, in the structure of the light-emitting element layer 400 including three or more stacks in accordance with an embodiment of the present disclosure, the following limitation may occur when only the first void 510 exists and the second void 520 does not exist. In this case, the first void 510 should serve to disconnect the first charge generation layers CGL1 of the sub-pixels adjacent to each other from each other and to disconnect the second charge generation layers CGL2 of the sub-pixels adjacent to each other from each other. In this case, although the first void 510 may disconnect the first charge generation layers CGL1 of the sub-pixels adjacent to each other from each other and to disconnect the second charge generation layers CGL2 of the sub-pixels adjacent to each other from each other, the first charge generation layer CGL1 and the second charge generation layer CGL2 arranged in the vertical direction and disposed on one side in the horizontal direction of the first void 510 may be connected to each other, and thus the forward leakage current may occur.

Accordingly, in the display panel and the display device according to the present disclosure, the first charge generation layer CGL1 and the second charge generation layer CGL2 respectively disposed in different layers and arranged in the vertical direction may be broken via the first void 510 and the second void 520 disposed in different layers and arranged in the vertical direction, respectively, thereby preventing the first charge generation layer CGL1 and the second charge generation layer CGL2 arranged in the vertical direction from being connected to each other. Accordingly, according to the present disclosure, the occurrence of the forward leakage current that may occur due to the short-circuit between the charge generation layers arranged in the vertical direction may be reduced.

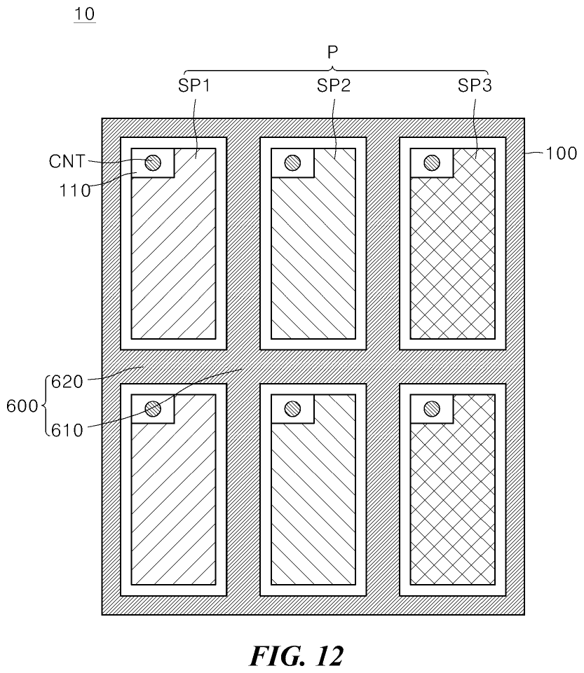

Hereinafter, a display panel 10 and a display device 1 according to another embodiment of the present disclosure will be described with reference to FIGS. 12 to 19. Hereinafter, the display panel 10 and the display device 1 according to another embodiment will be described based on differences thereof from the display panel 10 and the display device 1 according to the above-described embodiment, and the description of duplicate contents will be omitted.

Referring to FIG. 12, FIG. 12 is an enlarged plan view of two pixels P adjacent to each other, and is illustrated based on a 2×3 matrix structure. Each pixel P may include a first sub-pixel P, a second sub-pixel SP2, and a third sub-pixel SP3.

The structure 600 may be disposed between ones of a plurality of sub-pixels SP adjacent to each other. The structure 600 may include the anchor 610 and the stem 620 supported on the anchor 610 and extending in one direction. The anchor 610 may be disposed at a point where the first direction and the second direction intersect each other. Accordingly, the anchor 610 may be disposed at the corner where four sub-pixels are adjacent to each other based on the arrangement structure of the sub-pixels of the 2×2 matrix. The stem 620 may extend from the anchor 610 and may be disposed between ones of a plurality of sub-pixels SP adjacent to each other in each of the first direction DR1 and the second direction DR2 and may extend in each of the first direction DR1 and the second direction DR2. The stem 620 may extend to connect ones of the plurality of anchors 610 adjacent to each other to each other.

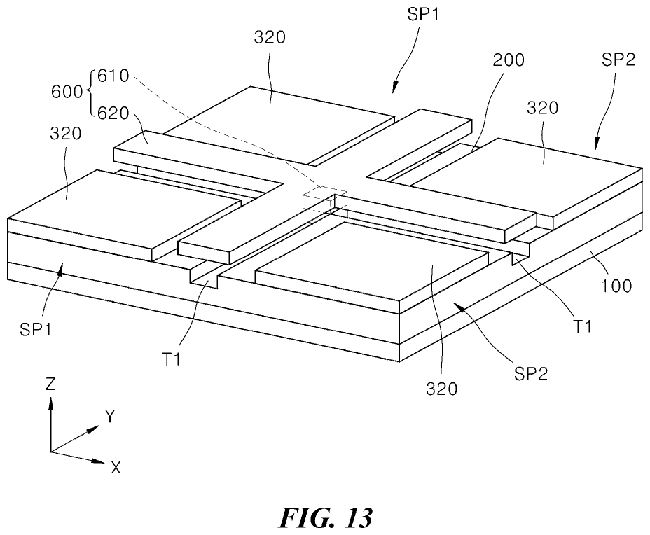

Hereinafter, an arrangement structure of the structure 600 will be described in more detail with further reference to FIG. 13. FIG. 13 is illustrated based on a sub-pixel arrangement structure of a 2×2 matrix on the substrate 100. In a state in which the structure 600 is not disposed, the structure is the same as that described above with reference to FIG. 3, and thus details thereof will be omitted.

FIG. 13 illustrates that the first trench T1 is formed on the substrate 100 and the structure 600 is additionally disposed thereon. The structure 600 may be spaced apart from the first trench T1 by a predetermined distance in the vertical manner and may extend along the extension of the first trench T1 and may be disposed on top of the first trench T1. The structure 600 may include the anchor 610 supported on the support 210 as the remaining portion of the insulating layer 200, and the stem 620 extending from the anchor 610 and along each of the first direction and the second direction.

The anchor 610 may serve as a pillar supporting the overall shape of the structure 600. Since the anchor 610 is disposed to be in contact with the support 210 as the portion of the insulating layer 200, the support 210 may directly support the anchor 610. However, embodiments of the present disclosure are not limited thereto. For example, an additional support layer may be disposed between the support 210 as the portion of the insulating layer 200 and the anchor 610, so that the support 210 may indirectly support the anchor 610 while the additional support layer is interposed therebetween.

The stem 620 may extend from the anchor 610 and along each of the first direction and the second direction. The stem 620 extending as described above may extend in the same direction as the direction in which the first trench T1 extends, and may be disposed to be spaced apart from the insulating layer 200 by a predetermined distance in the vertical direction. That is, the anchor 610 of the structure 600 may be supported on the insulating layer 200. Thus, even when the stem 620 is spaced apart from the insulating layer 200 by a predetermined distance in the vertical manner, the stem 620 may be reliable supported by the anchor with which the stem is monolithic or integrated.

The stem 620 may be disposed to overlap the first trench T1 in the vertical direction. Accordingly, in the top plan view, at least a partial area of the first trench T1 may be covered with the stem 620. The left-right width of the stem 620 may be smaller than the left-right width of the first trench T1. However, embodiments of the present disclosure are not limited thereto, and the left-right width of the stem 620 may be substantially the same as the left-right width of the first trench T1. An uppermost surface of the anchor 610 may be coplanar with an uppermost surface of the stem 620. Accordingly, the upper surface of the anchor 610 and the upper surface of the stem 620 may be coplanar with each other.

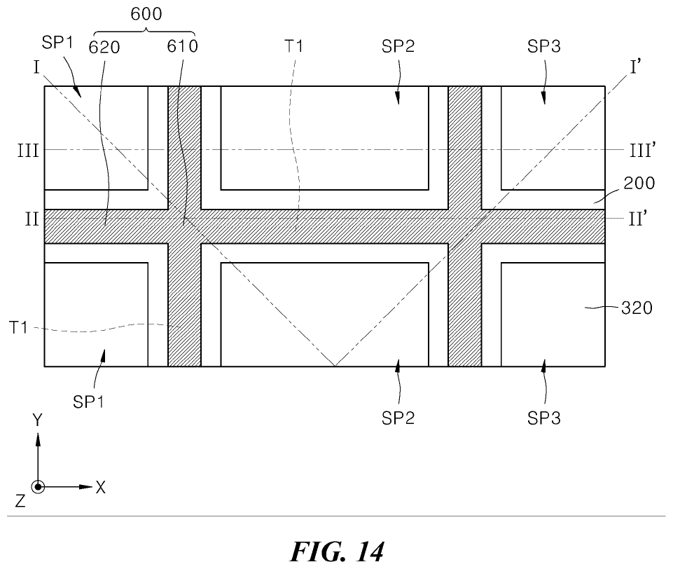

Hereinafter, a cross-sectional structure in a state where the structure 600 is formed on top of the first trench T1 will be described in more detail with further reference to FIGS. 14 to 19.

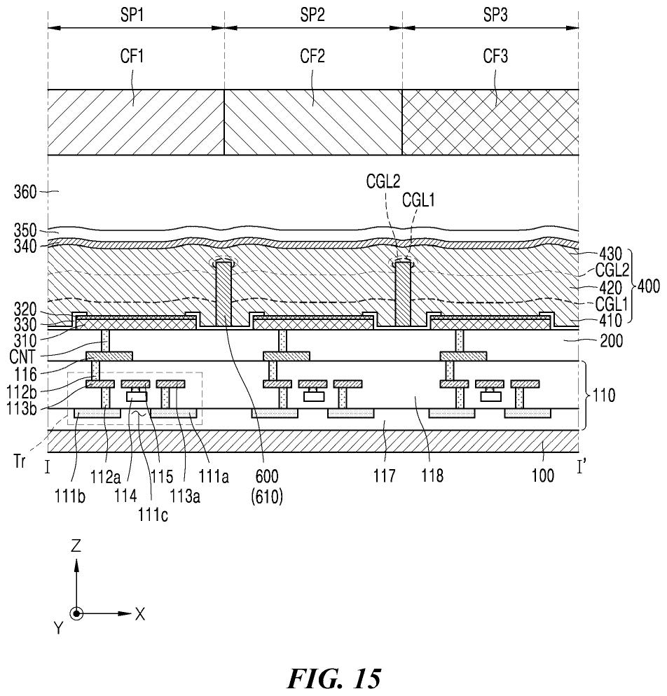

Referring to FIG. 15, the structure 600 may prevent the connection between the first charge generation layers CGL1 adjacent to each other horizontally and may prevent the connection between the second charge generation layers CGL2 adjacent to each other horizontally. Specifically, a lower end of the anchor 610 of the structure 600 may be supported on the fence 330 disposed on the insulating layer 200 and the anchor may extend upwardly to extend through the first charge generation layer CGL1 and the second charge generation layer CGL2. That is, a vertical level of an upper end of the anchor 610 may be higher than a vertical level of the upper surface of the second charge generation layer CGL2. However, in a state in which the structure 600 has been formed, the first charge generation layer CGL1 and the second charge generation layer CGL2 may be sequentially deposited thereon in terms of the formation process. Thus, a portion of the first charge generation layer CGL1 and a portion of the second charge generation layer CGL2 may be sequentially stacked on the upper end of the anchor 610. However, each of the portion of the first charge generation layer CGL1 and the portion of the second charge generation layer CGL2 formed on the upper end of the anchor 610 may not extend continuously but may be disconnected from each of the first charge generation layer CGL1 and the second charge generation layer CGL2 disposed in the sub-pixel due to a difference between the vertical level of the top surface of the anchor 610 extending upwardly through the second charge generation layer CGL2 and the vertical level of the upper surface of the second charge generation layer CGL2. As described above, the anchor 610 of the structure 600 may not only prevent the connection between the first charge generation layers CGL1 respectively disposed in the sub-pixels SP disposed adjacent to each other, but also may prevent the connection between the second charge generation layers CGL2 respectively disposed in the sub-pixels SP disposed adjacent to each other.

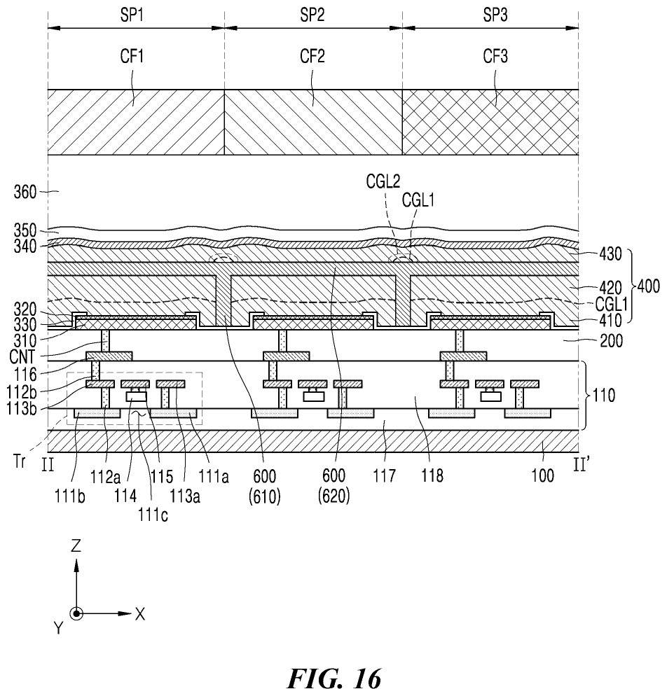

Referring to FIG. 16, the stem 620 may be disposed on top of the first charge generation layer CGL1 and may be disposed at substantially the vertical level as that of the second charge generation layer CGL2. Accordingly, the stem 620 may be disposed to overlap the second charge generation layer CGL2 in the horizontal direction. That is, the stem 620 and the second charge generation layer CGL2 may have the same vertical level. Thus, the stem 620 may prevent the connection between the second charge generation layers CGL2 adjacent to each other horizontally. In this case, it may be identified that the first charge generation layers CGL1 adjacent to each other horizontally and disconnected from each other, and the second charge generation layers CGL2 adjacent to each other horizontally and disconnected from each other are disposed on top of the anchor 610. Therefore, according to the present disclosure, even in the area where the anchor 610 is disposed, the first charge generation layers CGL1 respectively disposed in the adjacent sub-pixels may be disconnected from each other, while the second charge generation layers CGL2 respectively disposed in the adjacent sub-pixels may be disconnected from each other.

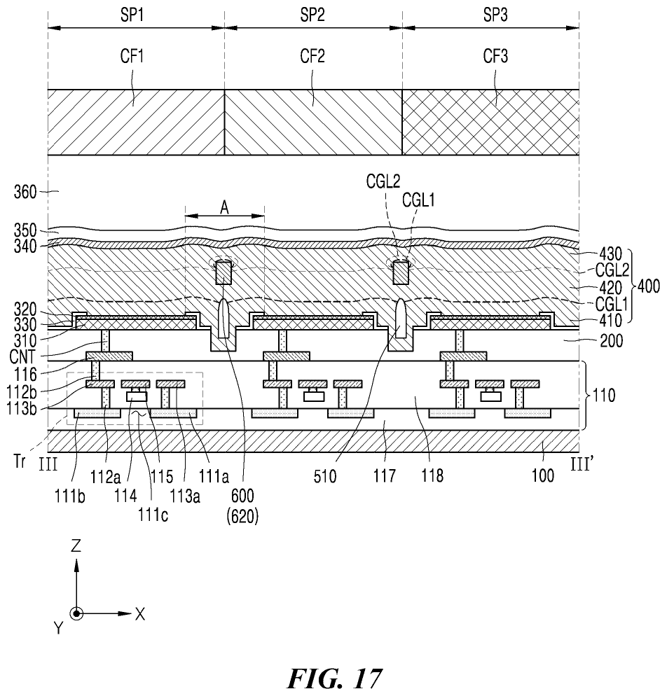

Referring to FIG. 17, the first trench T1 may be formed at a boundary between the sub-pixels SP adjacent to each other. The first trench T1 may be defined by the pair of fences 330 disposed on the insulating layer 200 and respectively disposed on both opposing sides of the first trench T1 and on top of the first trench T1. The stem 620 may be positioned to overlap the first trench T1 in the vertical direction and may be formed on top of the first trench T1. The first void 510 may be formed in the first trench T1. The first void 510 may be disposed inside the first trench T1 and may be disposed to overlap the stem 620 in the vertical direction.

At least a portion of the first stack 410 included in the light-emitting element layer 400 may be broken or discontinuous due to the first void 510 in the first trench T1. In some cases, a portion of the first stack 410 may extend continuously in the first trench T1.

The first charge generation layer CGL1 may be broken or discontinuous inside the first trench T1 or on top of the first trench T1. In addition, the second stack 420 may extend continuously on top of the first trench T1. However, a portion of the second stack 420 may be broken or discontinuous on top of the first trench T1. Accordingly, the first void 510 may be formed inside the light-emitting element layer 400 in the area overlapping the first trench T1, and the first void 510 may serve to disconnect the first charge generation layers CGL1 respectively disposed in adjacent ones of the plurality of sub-pixels from each other.

The stem 620 disposed on top of the first trench T1 may be spaced apart from the first void 510 by a predetermined distance in the vertical manner and may be disposed to overlap the first void in the vertical direction. A vertical level of a lower end of the stem 620 may be higher than a vertical level of an upper surface of the first charge generation layer CGL1, while a vertical level of an upper end of the stem 620 may be higher than a vertical level of the upper surface of the second charge generation layer CGL2. The stem 620 may be disposed between the second stack 420 and the third stack 430. Accordingly, at least a portion of the second stack 420 included in the light-emitting element layer 400 may be broken due to the stem 620. The second charge generation layer CGL2 may be broken or discontinuous due to the stem 620. Further, a portion of the third stack 430 may extend continuously while being disposed on top of the stem 620. However, a portion of the third stack 430 may be broken or discontinuous due to the stem 620. Accordingly, the stem 620 may serve to disconnect the second charge generation layers CGL2 respectively disposed in ones of the plurality of sub-pixels adjacent to each other from each other.

As described above, the stem 620 may prevent the connection between the second charge generation layers CGL2 adjacent to each other in the horizonal direction. As described above, a vertical level of the upper end of the stem 620 may be higher than a vertical level of the upper surface of the second charge generation layer CGL2. However, in a state in which the structure 600 has been formed, the first charge generation layer CGL1 and the second charge generation layer CGL2 may be sequentially deposited thereon in terms of the formation process. Thus, a portion of the first charge generation layer CGL1 and a portion of the second charge generation layer CGL2 may be sequentially stacked on the upper end of the stem 620. However, each of the portion of the first charge generation layer CGL1 and the portion of the second charge generation layer CGL2 formed on the upper end of the stem 620 may not extend continuously but may be disconnected from each of the first charge generation layer CGL1 and the second charge generation layer CGL2 disposed in the sub-pixel due to a difference between the vertical level of the upper surface of the stem 620 and the vertical level of the upper surface of the second charge generation layer CGL2. As described above, the stem 620 of the structure 600 may not only prevent the connection between the first charge generation layers CGL1 respectively disposed in the sub-pixels SP disposed adjacent to each other, but also may prevent the connection between the second charge generation layers CGL2 respectively disposed in the sub-pixels SP disposed adjacent to each other.

A left-right width of the stem 620 may be set to a range sized such that the stem 620 prevents the connection between the second charge generation layers CGL2 respectively disposed in the sub-pixels SP disposed adjacent to each other, and the formation of the first void 510 disposed thereunder is not prevented. To this end, it is preferable that the left-right width of the stem 620 is set not to exceed a distance between both opposing ends of a combination of the pair of fences 330 respectively disposed at both opposing sides of the first trench T1. The distance between both opposing ends of the combination of the pair of fences 330 may be defined as a stem formation area A.

In addition, it is preferable that the left-right width of the stem 620 is within a range sized such that the stem does not invade the light-emitting area of the sub-pixel SP. The light emission area of the sub-pixel SP may be the same as an exposed area of the first electrode 320 that is not covered with the fences 330. That is, it is preferable that the stem 620 is disposed so as not to overlap the first electrode 320 in the vertical direction. Accordingly, this may prevent a decrease in luminance due to a decrease in a light output area that may occur when the stem 620 invades the light emission area of the sub-pixel SP.

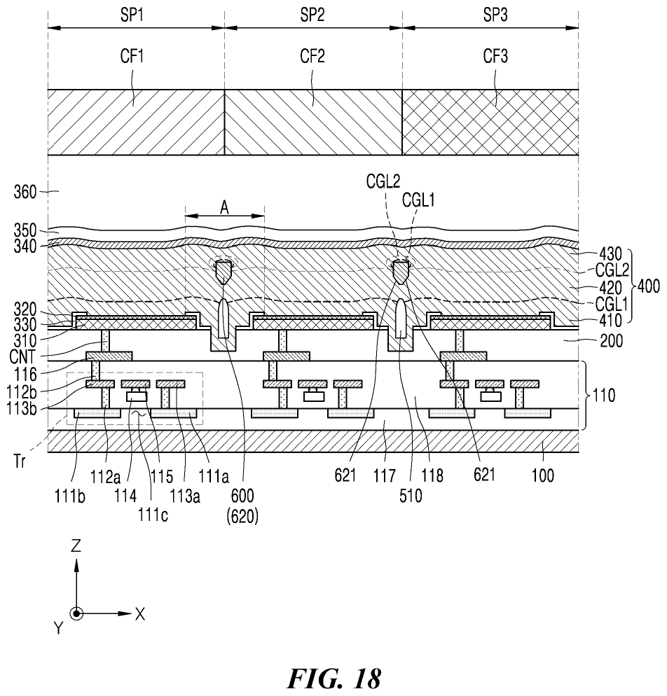

Referring to FIG. 18, according to another embodiment, an outer side surface of a lower portion of the stem 620 be an inclined surface 621 inclined downwardly toward a center of the first trench T1. In an example, the lower portion of the stem 620 in the side cross-sectional view of FIG. 18 includes a pair of inclined surface 621 has both opposing outer side surfaces extending in the inclined manner. Thus, a pair of opposing inclined surfaces 621 may face each other and may be inclined downwardly toward a center of the first trench T1. When the lower end of the stem 620 is disposed adjacent to the first trench T1, in the process of depositing the light-emitting element layer 400 in the first trench T1 to form the first void 510, a deposition shadowing phenomenon may occur in which the lower end of the stem 620 interferes with the deposition. Therefore, according to the present disclosure, the outer side surface of the lower portion of the stem 620 may be the inclined surface 621, such that the deposition shadowing phenomenon on the first trench T1 which may be generated due to the lower portion of the stem 620 may be reduced, and thus the first void 510 may be smoothly formed in the first trench T1.

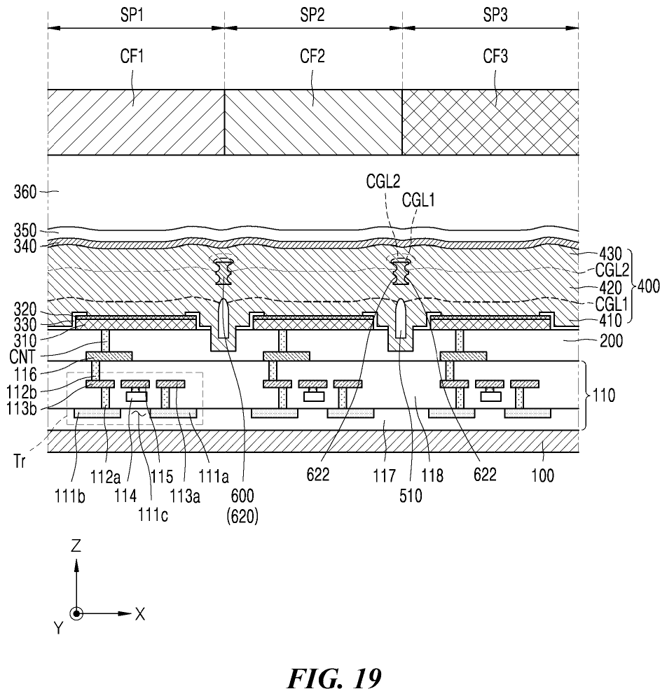

Referring to FIG. 19, according to still another embodiment of the present disclosure, a side surface of the stem 620 may include one or more curved portions 622. For example, the curved portion 622 may be a scallop pattern having a continuous curved shape or an undercut pattern patterned in a manner in which a partial area of the side surface is removed. In a side cross-sectional view of FIG. 19, the curved portion 622 may be formed in each of both opposing side surfaces of the stem 620. As the side surface of the stem 620 is formed to include the curved portion 622, the disconnection between the second charge generation layers CGL2 respectively disposed in adjacent ones of the sub-pixels may be more easily achieved, thereby increasing the disconnection effect between the second charge generation layers CGL2.

In the display panel and the display device according to the present disclosure described above, the short-circuit between the first charge generation layers CGL1 of the sub-pixels adjacent to each other may be prevented via the first trench T1 defined between adjacent ones of the plurality of sub-pixels, and the short-circuit between the second charge generation layers CGL2 of the sub-pixels adjacent to each other may be prevented via the stem 620.

That is, the first trench T1 may disconnect the first charge generation layers CGL1 adjacent to each other in the horizontal direction from each other, and the stem 620 may disconnect the second charge generation layers CGL2 adjacent to each other in the horizontal direction from each other. Accordingly, according to the present disclosure, the generation of the lateral leakage current that may occur due to the short-circuit between the charge generation layers of the neighboring sub-pixels.

In one example, in the structure of the light-emitting element layer 400 including three or more stacks in accordance with an embodiment of the present disclosure, the following limitation may occur when only the first void 510 exists and the stem 620 does not exist. In this case, the first void 510 should serve to disconnect the first charge generation layers CGL1 of the sub-pixels adjacent to each other from each other and to disconnect the second charge generation layers CGL2 of the sub-pixels adjacent to each other from each other. In this case, although the first void 510 may disconnect the first charge generation layers CGL1 of the sub-pixels adjacent to each other from each other and to disconnect the second charge generation layers CGL2 of the sub-pixels adjacent to each other from each other, the first charge generation layer CGL1 and the second charge generation layer CGL2 arranged in the vertical direction and disposed on one side in the horizontal direction of the first void 510 may be connected to each other, and thus the forward leakage current may occur.

Accordingly, in the display panel and the display device according to the present disclosure, the first charge generation layer CGL1 and the second charge generation layer CGL2 respectively disposed in different layers and arranged in the vertical direction may be broken via the first void 510 and the stem 620 disposed in different layers and arranged in the vertical direction, respectively, thereby preventing the first charge generation layer CGL1 and the second charge generation layer CGL2 arranged in the vertical direction from being connected to each other. Accordingly, according to the present disclosure, the occurrence of the forward leakage current that may occur due to the short-circuit between the charge generation layers arranged in the vertical direction may be reduced.

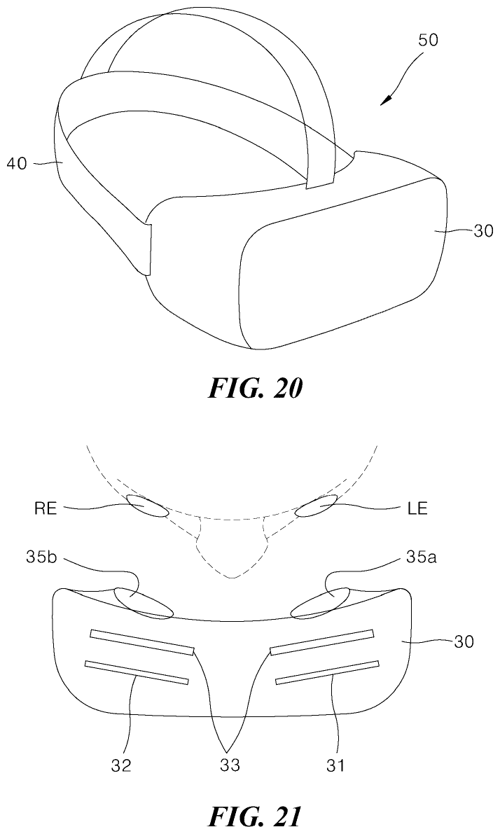

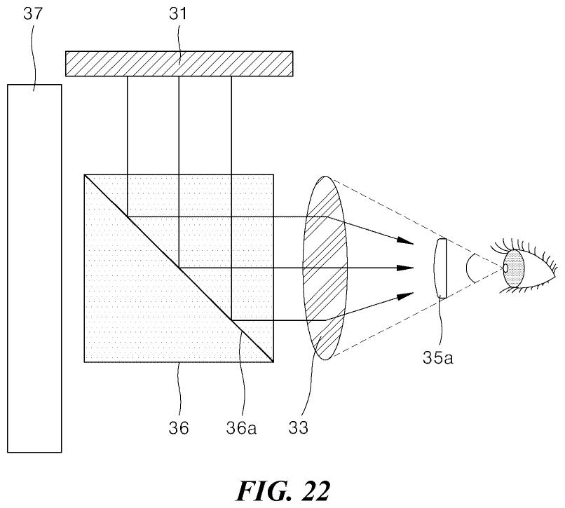

FIGS. 20 to 22 are diagrams of head-mounted display apparatuses including a display device according to an embodiment of the present disclosure. Specifically, FIG. 20 is a schematic perspective view of a head-mounted display apparatus including a display device according to an embodiment of the present disclosure, and FIG. 21 is a top view showing a head-mounted display apparatus implementing virtual reality. FIG. 22 is a side view showing a head-mounted display apparatus that implements augmented reality.

Referring to FIG. 20, the head-mounted display apparatus 50 including a display device according to an embodiment of the present disclosure may include a casing 30 and a head mounting band 40. The casing 30 may receive therein components such as a display device, a lens array, an eyepiece, a sound device, an accelerometer, and a position sensor, etc. The head mounting band 40 is fixed to the casing 30. The head mounting band 40 is illustrated as being formed to surround an upper surface and both opposing side surfaces of the user's head. However, embodiments of the present disclosure are not limited thereto. The head mounting band 40 is used to secure the head-mounted display apparatus 50 to the user's head. In another example, the head mounting band 40 may be embodied as an eyeglass frame or a helmet-shaped structure that entirely surrounds the user's head. The head-mounted display apparatus 50 may include the display device according to an embodiment of the present disclosure as described above, and may provide an image implementing virtual reality (VR) or an image implementing augmented reality (AR) to the user.

Referring to FIG. 21, the head-mounted display apparatus 50 implementing virtual reality may include a first display panel 31, a second display panel 32, a first lens 33, a left eye eyepiece 35a, and a right eye eyepiece 35b. The first display panel 31 may be referred to as a left-eye display panel, the second display panel 32 may be referred to as a right-eye display panel, the first lens 33 may be referred to as a lens array, and the left-eye eyepiece 35a and the right-eye eyepiece 35b may be referred to as a pair of second lenses. The first display panel 31, the second display panel 32, the first lens 33, and the left-eye eyepiece 35a and the right-eye eyepiece 35b may be accommodated in the casing 30.

The first display panel 31 and the second display panel 32 may display the same image. When the same image is implemented in the first display panel 31 and the second display panel 32, respectively, the user may watch the 2D image through the head-mounted display apparatus 50. Alternatively, the first display panel 31 may display a left-eye image, and the second display panel 32 may display a right-eye image different from the left-eye image. In this case, the user may view the stereoscopic image through the head-mounted display apparatus 50. Each of the first display panel 31 and the second display panel 32 may include one of the display panel according to the above-described embodiment of the present disclosure and a modified example thereof.

The first lens 33 may be spaced apart from each of the left eye eyepiece 35a and the first display panel 31, and may be disposed between the left eye eyepiece 35a and the first display panel 31. That is, the first lens 33 may be positioned in front of the left eye eyepiece 35a and in rear of the first display panel 31. In addition, the first lens 33 may be spaced apart from each of the right-eye eyepiece 35b and the second display panel 32, and may be disposed between the right-eye eyepiece 35b and the second display panel 32. That is, the first lens 33 may be positioned in front of the right eye eyepiece 35b and in rear of the second display panel 32. The first lens 33 may include a micro lens array. However, embodiments of the present disclosure are not limited thereto. In an example, the first lens 33 may include a pinhole array. The image displayed on the first display panel 31 or the second display panel 32 via the first lens 33 may be visible to the user in an enlarged manner. A left eye LE of the user may be positioned in rear of the left eye eyepiece 35a, and a right eye RE of the user may be positioned in rear of the right eye eyepiece 35b.

Referring to FIG. 22, the head-mounted display apparatus 50 implementing augmented reality may include the first display panel 31, the first lens 33, a left eye eyepiece 35a, a transmissive and reflective portion 36, and a transmissive window 37. For convenience of description, only the configuration of the left eye is illustrated in FIG. 22, and the configuration of the right eye may be the same as or similar to the configuration of the left eye.

The first display panel 31, the first lens 33, the left eye eyepiece 35a, the transmissive and reflective portion 36, and a transmissive window 37 may be accommodated in the casing 30. The first display panel 31 may be disposed on one side of the transmissive and reflective portion 36, for example, on an upper side thereof so that the first display panel 31 does not block the transmissive window 37. Accordingly, the first display panel 31 may provide an image to the transmissive and reflective portion 36 without blocking an external background visible through the transmissive window 37. The first display panel 31 may include one of the display panel according to the above-described embodiment of the present disclosure and a modified example thereof. The first lens 33 may be provided between the left eye eyepiece 35a and the transmissive and reflective portion 36. The user's left eye is positioned in rear of the left eye eyepiece 35a.

The transmissive and reflective portion 36 is disposed between the first lens 33 and the transmissive window 37. The transmissive and reflective portion 36 may include a transmissive and reflective surface 36a that transmits a portion of light therethrough and reflects the other portion of light therefrom. The transmissive and reflective surface 36a includes a semi-transmissive metal film. For example, the semi-transmissive metal film may be made of a semi-transmissive metal material such as magnesium (Mg), silver (Ag), or an alloy of magnesium (Mg) and silver (Ag). The transmissive and reflective surface 36a may be formed to allow the image displayed from the first display panel 31 to be directed to the first lens 33. Therefore, the user may view both the external background visible through the transmissive window 37 and the image displayed from the first display panel 31. In other words, the user may view both the real background and the virtual image as one image in an overlapping manner. Thus, the augmented reality may be implemented.

The display panel and the display device according to aspects and embodiments of the present disclosure as described above may be described as follows.

A first aspect of the present disclosure provides a display panel comprising: a substrate having a plurality of sub-pixel areas corresponding to a plurality of sub-pixels; an insulating layer disposed on the substrate; a first trench defined in the insulating layer, wherein the first trench is disposed between adjacent ones of the plurality of sub-pixel areas; and a structure disposed on the first trench and spaced apart from the first trench, wherein the structure extends along an extension direction of the first trench.

In accordance with the first aspect of the present disclosure, the first trench extends along a first direction and a second direction intersecting each other in a plan view of the display device, wherein a portion of the insulating layer remains in an area where the first trench extending along the first direction and the first trench extending along the second direction intersect each other, and the remaining portion of the insulating layer acts as a support supporting the structure thereon.

In accordance with the first aspect of the present disclosure, the structure includes: an anchor disposed on the insulating layer; and a stem extending from the anchor and along a first direction and a second direction intersecting each other in a plan view of the display device.

In accordance with the first aspect of the present disclosure, the anchor is supported on the insulating layer, wherein the stem is disposed to be spaced apart from the first trench by a predetermined distance.

In accordance with the first aspect of the present disclosure, the stem extending along the first direction and the second direction includes a pair of stems spaced apart from each other in a horizontal direction, wherein each of the pair of stems extends along the extension of the first trench.

In accordance with the first aspect of the present disclosure, a second trench is defined between the pair of stems extending in the same direction, and the second trench extends along the first trench, wherein the second trench overlaps the first trench in a vertical direction.

In accordance with the first aspect of the present disclosure, the structure further includes a protrusion protruding from the anchor upwardly beyond the stem.

In accordance with the first aspect of the present disclosure, each of the stem extending along the first direction and the stem extending in the second direction overlaps the first trench in a vertical direction.

In accordance with the first aspect of the present disclosure, the display panel further comprises a light-emitting element layer disposed on the insulating layer, wherein the light-emitting element layer includes a first stack, a first charge generation layer, a second stack, a second charge generation layer, and a third stack sequentially stacked upwardly on the insulating layer, wherein the anchor is constructed to: prevent an electrical connection between the first charge generation layers respectively disposed in ones of the plurality of sub-pixel areas adjacent to each other; and prevent an electrical connection between the second charge generation layers respectively disposed in ones of the plurality of sub-pixel areas adjacent to each other.

A second aspect of the present disclosure provides a display panel comprising: a substrate having a plurality of sub-pixel areas corresponding to a plurality of sub-pixels; an insulating layer disposed on the substrate; a first trench defined in the insulating layer, wherein the first trench is disposed between adjacent ones of the plurality of sub-pixel areas; and a second trench disposed on top of the first trench and spaced apart from the first trench, wherein the second trench overlaps the first trench in a vertical direction.

In accordance with the second aspect of the present disclosure, the display panel further comprises: a first void disposed inside the first trench; and a second void disposed inside the second trench and overlapping the first void in the vertical direction.

In accordance with the second aspect of the present disclosure, the display panel further comprises a light-emitting element layer disposed on the insulating layer, wherein the light-emitting element layer includes a first stack, a first charge generation layer, a second stack, a second charge generation layer, and a third stack sequentially stacked upwardly on the insulating layer, wherein the first void is constructed to prevent an electrical connection between the first charge generation layers respectively disposed in ones of the plurality of sub-pixel areas adjacent to each other, wherein the second void is constructed to prevent an electrical connection between the second charge generation layers respectively disposed in ones of the plurality of sub-pixel areas adjacent to each other.

In accordance with the second aspect of the present disclosure, the display panel further comprises a structure including a pair of stems spaced apart from each other in a horizontal direction such that the second trench is defined therebetween.

In accordance with the second aspect of the present disclosure, the pair of stems is disposed between the first charge generation layer and the second charge generation layer in a vertical direction.

In accordance with the second aspect of the present disclosure a side surface of a lower portion of the stem in inclined downwardly toward a center of the first trench.

A third aspect of the present disclosure provides a display panel, comprising: a substrate having a plurality of sub-pixel areas corresponding to a plurality of sub-pixels; an insulating layer disposed on the substrate; a first trench defined in the insulating layer, wherein the first trench is disposed between adjacent ones of the plurality of sub-pixel areas; and a structure disposed on the first trench and spaced apart from the first trench, wherein the structure includes a stem overlapping the first trench in a vertical direction.

In accordance with the third aspect of the present disclosure, the display panel further comprises a first void disposed inside the first trench, wherein the first void overlaps the stem in the vertical direction.

In accordance with the third aspect of the present disclosure, the display panel further comprises a light-emitting element layer disposed on the insulating layer, wherein the light-emitting element layer includes a first stack, a first charge generation layer, a second stack, a second charge generation layer, and a third stack sequentially stacked upwardly on the insulating layer, wherein the first void is constructed to prevent an electrical connection between the first charge generation layers respectively disposed in ones of the plurality of sub-pixel areas adjacent to each other, wherein the stem is constructed to prevent an electrical connection between the second charge generation layers respectively disposed in ones of the plurality of sub-pixel areas adjacent to each other.

In accordance with the third aspect of the present disclosure, a side surface of a lower portion of the stem in inclined downwardly toward a center of the first trench.

In accordance with the third aspect of the present disclosure, a side surface of the stem includes at least one curved portion.

A fourth aspect of the present disclosure provides a display device comprising: a casing; and at least one display panel accommodated in the casing, wherein each of the at least one display panel includes the display panel according to one of the first to third aspects and the embodiments thereof.

In accordance with the fourth aspect of the present disclosure, the at least one display panel includes a first display panel and a second display panel spaced apart from each other, wherein the casing further accommodates therein a left eye lens disposed between the first display panel and a left eye of a user, and a right eye lens disposed between the second display panel and a right eye of the user.

Although some embodiments of the present disclosure have been described above with reference to the accompanying drawings, the present disclosure may not be limited to some embodiments and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that some embodiments as described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel comprising:
a substrate having a plurality of sub-pixel areas and a plurality of sub-pixels corresponding to the plurality of sub-pixel areas;
an insulating layer disposed on the substrate;
a first trench in the insulating layer, wherein the first trench is disposed between adjacent or successive ones of the plurality of sub-pixel areas; and
a structure disposed above and spaced apart from the first trench, wherein the structure extends along the first trench.

2. The display panel of claim 1, wherein the first trench extends along a first direction and a second direction of the substrate, and the first direction and the second direction intersect each other in a plan view of the display panel,
wherein a portion of the insulating layer is present where the first trench extending along the first direction and the first trench extending along the second direction intersect each other, and a remaining portion of the insulating layer is a support for the structure.

3. The display panel of claim 1, wherein the structure includes:
an anchor disposed on the insulating layer; and
a stem extending from the anchor in a first direction and a second direction relative to the substrate, wherein the first direction and the second direction intersect each other in a plan view of the display panel.

4. The display panel of claim 3, wherein the anchor is supported on the insulating layer, and
wherein the stem is spaced apart from the first trench by a distance.

5. The display panel of claim 3, wherein the stem includes a pair of stems spaced apart from each other in a horizontal direction, wherein each stem of the pair of stems extends along the first trench.

6. The display panel of claim 5, further comprising:
a second trench between the pair of stems that extends along the first trench, wherein the second trench overlaps the first trench in a vertical direction.

7. The display panel of claim 3, wherein the structure further includes a protrusion extending away from the anchor beyond the stem.

8. The display panel of claim 3, wherein the stem extending along the first direction and the stem extending in the second direction both overlap the first trench in a vertical direction.

9. The display panel of claim 3, wherein the display panel further comprises a light-emitting element layer disposed on the insulating layer,
wherein the light-emitting element layer includes a first stack, a first charge generation layer, a second stack, a second charge generation layer, and a third stack sequentially stacked on the insulating layer,
wherein the anchor is configured to prevent electrical connection between the first charge generation layer respectively disposed in adjacent or successive ones of the plurality of sub-pixel areas, and is further configured to prevent electrical connection between the second charge generation layer respectively disposed in adjacent or successive ones of the plurality of sub-pixel areas.

10. A display panel comprising:
a substrate having a plurality of sub-pixel areas and a plurality of sub-pixels corresponding to the plurality of sub-pixel areas;
an insulating layer disposed on the substrate;
a first trench in the insulating layer, wherein the first trench is disposed between adjacent or successive ones of the plurality of sub-pixel areas; and
a second trench disposed above and spaced apart from the first trench, wherein the second trench overlaps the first trench in a vertical direction.

11. The display panel of claim 10, wherein the display panel further comprises:
a first void inside the first trench; and
a second void inside the second trench and overlapping the first void in the vertical direction.

12. The display panel of claim 11, wherein the display panel further comprises a light-emitting element layer disposed on the insulating layer,
wherein the light-emitting element layer includes a first stack, a first charge generation layer, a second stack, a second charge generation layer, and a third stack sequentially stacked on the insulating layer,
wherein the first void is configured to prevent electrical connection between the first charge generation layer respectively disposed in adjacent or successive ones of the plurality of sub-pixel areas, and
wherein the second void is configured to prevent electrical connection between the second charge generation layer respectively disposed in adjacent or successive ones of the plurality of sub-pixel areas.

13. The display panel of claim 12, wherein the display panel further comprises a pair of stems spaced apart from each other in a horizontal direction with the second trench between the pair of stems.

14. The display panel of claim 13, wherein the pair of stems is disposed between the first charge generation layer and the second charge generation layer in a vertical direction.

15. The display panel of claim 13, wherein a lower end of at least one of the pair of stems is inclined downward toward a center of the first trench.

16. A display panel, comprising:
a substrate having a plurality of sub-pixel areas and a plurality of sub-pixels corresponding to the plurality of sub-pixel areas;
an insulating layer disposed on the substrate;
a first trench in the insulating layer between adjacent or successive ones of the plurality of sub-pixel areas; and
a structure disposed above and spaced apart from the first trench,
wherein the structure includes a stem overlapping the first trench in a vertical direction.

17. The display panel of claim 16, wherein the display panel further comprises a first void inside the first trench,
wherein the first void overlaps the stem in the vertical direction.

18. The display panel of claim 17, wherein the display panel further comprises a light-emitting element layer disposed on the insulating layer,
wherein the light-emitting element layer includes a first stack, a first charge generation layer, a second stack, a second charge generation layer, and a third stack sequentially stacked on the insulating layer,
wherein the first void is configured to prevent electrical connection between the first charge generation layer respectively disposed in adjacent or successive ones of the plurality of sub-pixel areas, and
wherein the stem is configured to prevent electrical connection between the second charge generation layer respectively disposed in adjacent or successive ones of the plurality of sub-pixel areas.

19. The display panel of claim 16, wherein a lower end of the stem is inclined downward toward a center of the first trench.

20. The display panel of claim 16, wherein a side surface of the stem includes at least one curved portion.

21. A display device comprising:
a casing; and
at least one display panel accommodated in the casing, wherein each of the at least one display panel includes the display panel of claim 1.

22. The display device of claim 21, wherein the at least one display panel includes a first display panel and a second display panel spaced apart from each other,
wherein the casing further accommodates therein a left eye lens disposed between the first display panel and a left eye of a user, and a right eye lens disposed between the second display panel and a right eye of the user.
